(19) United States
(12) Patent Application Publication
(10) Pub. No.: US 2025/0038386 A1
(43) Pub. Date: Jan. 30, 2025

(54) FILTER

(71) Applicant: SOSHIN ELECTRIC CO., LTD., Saku-City (JP)

(72) Inventors: Shun SUZUKI, Saku-City (JP); Hiroyuki ISONO, Saku-City (JP); Kazuya ADACHI, Saku-City (JP); Kazuma KOSAKA, Saku-City (JP)

(73) Assignee: SOSHIN ELECTRIC CO., LTD., Saku-City (JP)

(21) Appl. No.: 18/841,416

(22) PCT Filed: Feb. 3, 2023
(86) PCT No.: PCT/JP2023/003517

§ 371 Date: Aug. 26, 2024

(30) Foreign Application Priority Data
Feb. 28, 2022 (JP) 2022-029201

(51) Int. Cl. H01P 1/20; H01P 7/10

(52) U.S. Cl. CPC H01P 1/2002; H01P 7/10

(57) ABSTRACT

A filter is provided with a plurality of resonators and a first capacitance coupling structure including a first electrode pattern, a second electrode pattern, and a first coupling capacitance electrode. A first dimensional difference, which is a value obtained by subtracting a dimension of the first coupling capacitance electrode in a width direction of the first coupling capacitance electrode from a dimension of the first electrode pattern in the width direction of the first coupling capacitance electrode, is 1.4 times or more of a first inter-electrode distance, which is a distance between the first coupling capacitance electrode and the first electrode pattern in a thickness direction of the first coupling capacitance electrode.

### TECHNICAL FIELD

The present invention relates to a filter.

### BACKGROUND ART

A resonator has been proposed having a strip line that faces toward a shielding conductor formed on one main surface side of a dielectric substrate, and a via electrode one end of which is connected to a shielding conductor formed on another main surface side of the dielectric substrate, and another end of which is connected to the strip line (see, JP 2020-198482 A).

### SUMMARY OF THE INVENTION

There is a long awaited need for a technology that can realize more satisfactory filter characteristics.

The present invention has the object of solving the aforementioned problem.

A filter according to one aspect of the present invention includes a plurality of resonators formed inside a dielectric substrate, and each of which is equipped with a via electrode portion, and a first capacitive coupling structure including a first electrode pattern connected to any one from among the plurality of via electrode portions, a second electrode pattern connected to any one from among the plurality of via electrode portions, and a first coupling capacitance electrode one end of which overlaps the first electrode pattern as viewed in plan, and another end of which overlaps the second electrode pattern as viewed in plan, wherein a dimension of the first coupling capacitance electrode in a widthwise direction of the first coupling capacitance electrode is smaller than a dimension of the first electrode pattern in the widthwise direction of the first coupling capacitance electrode, on both sides of a first region in which the first coupling capacitance electrode and the first electrode pattern overlap, there exist second regions in which the first coupling capacitance electrode does not overlap with the first electrode pattern, and a first dimensional difference, which is a value obtained by subtracting the dimension of the first coupling capacitance electrode in the widthwise direction of the first coupling capacitance electrode from the dimension of the first electrode pattern in the widthwise direction of the first coupling capacitance electrode, is greater than or equal to 1.4 times a first inter-electrode distance, which is a distance between the first coupling capacitance electrode and the first electrode pattern in a thickness direction of the first coupling capacitance electrode.

According to the present invention, it is possible to provide a filter having satisfactory characteristics.

### BRIEF DESCRIPTION OF DRAWINGS

FIG. 1 is a perspective view showing the filter according to an embodiment;

FIG. 2 is a plan view showing the filter according to the embodiment;

FIG. 3A is a cross-sectional view showing a portion of the filter according to the embodiment;

FIG. 3B is a cross-sectional view showing a portion of the filter according to the embodiment;

FIG. 4 is a perspective view showing the filter according to the embodiment;

FIG. 5 is a perspective view showing the filter according to the embodiment;

FIG. 6 is a plan view showing the filter according to the embodiment;

FIG. 7 is a perspective view showing the filter according to the embodiment;

FIG. 8 is a plan view showing the filter according to the embodiment;

FIG. 9 is a perspective view showing the filter according to the embodiment;

FIG. 10 is a plan view showing the filter according to the embodiment;

FIG. 11 is a plan view showing the filter according to the embodiment;

FIG. 12 is a plan view showing an example of a filter according to a modified embodiment;

FIG. 13 is a plan view showing an example of a filter according to a modified embodiment; and

FIG. 14 is a plan view showing an example of a filter according to a modified embodiment.

### DETAILED DESCRIPTION OF THE INVENTION

### Embodiment

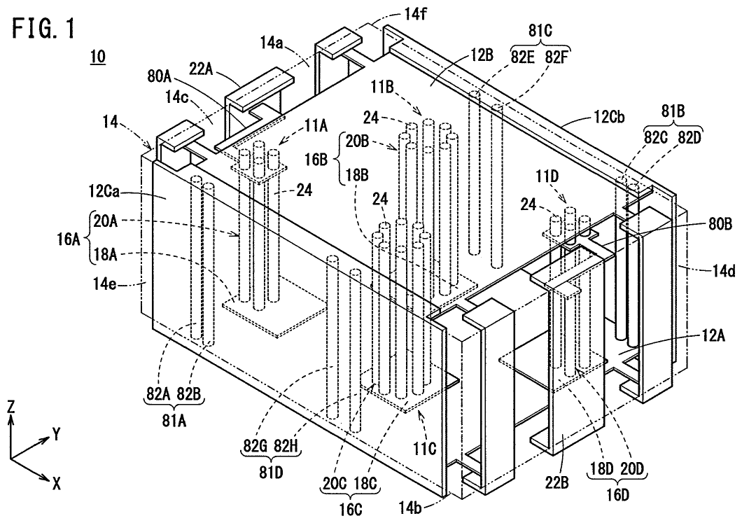

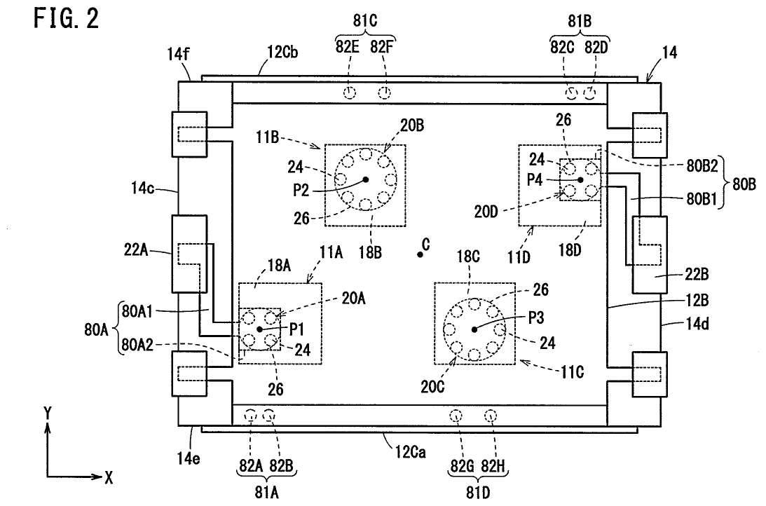

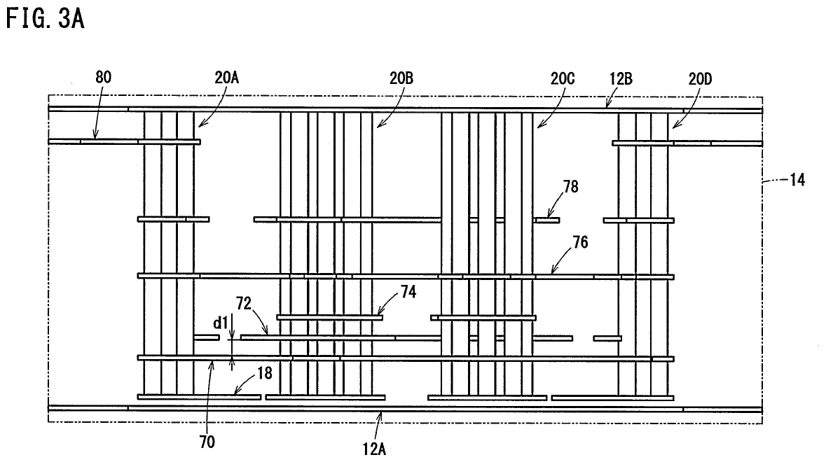

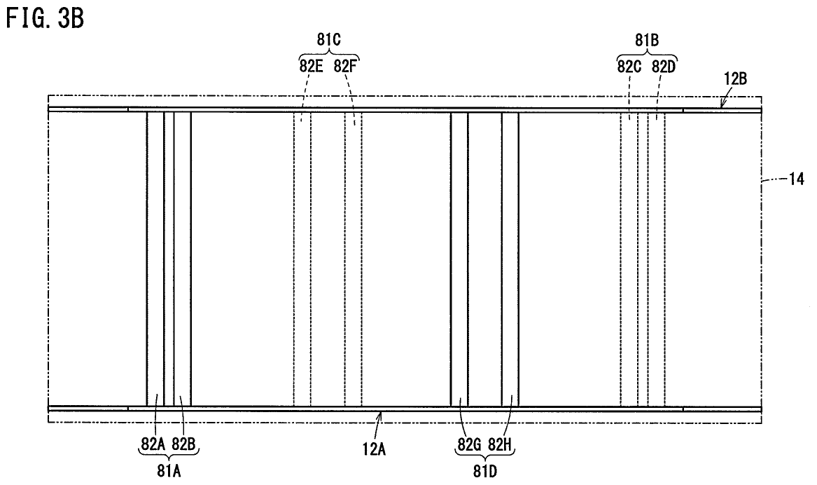

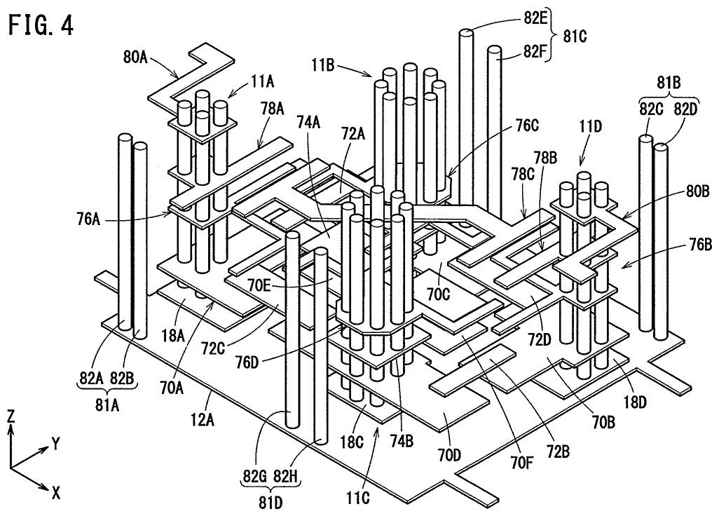

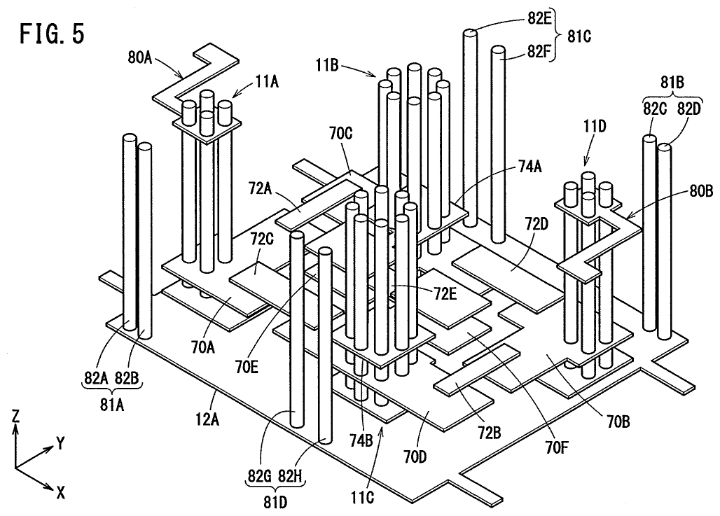

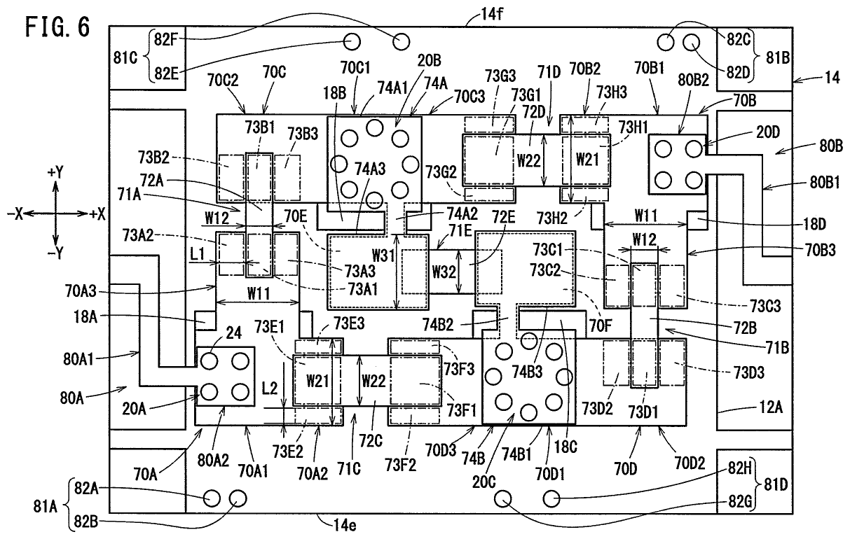

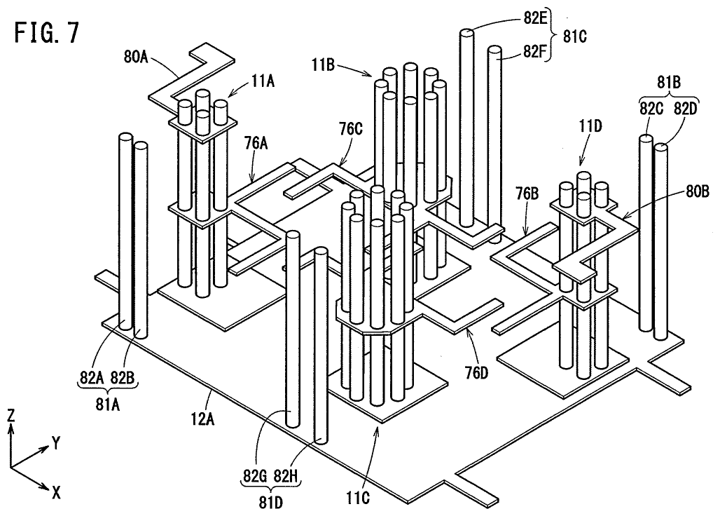

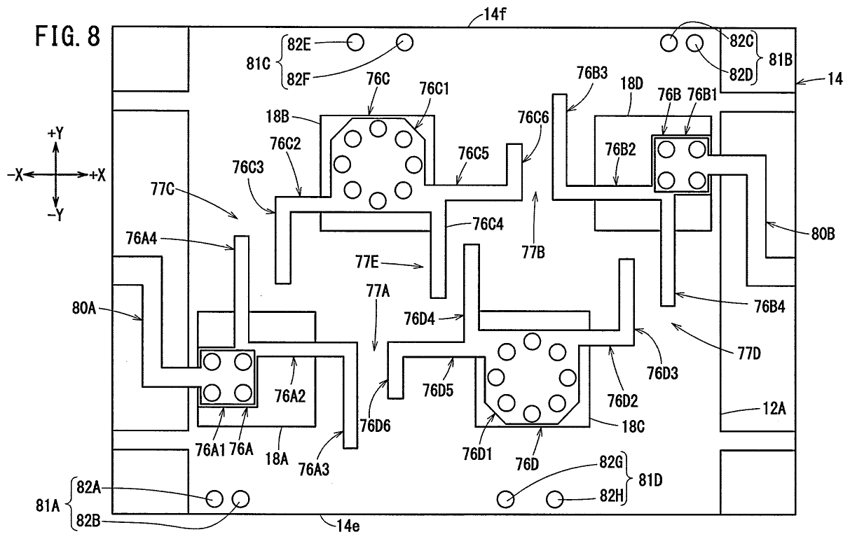

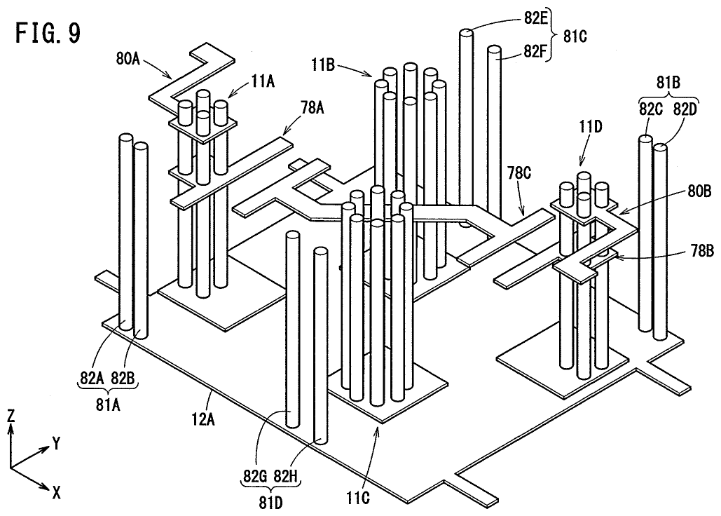

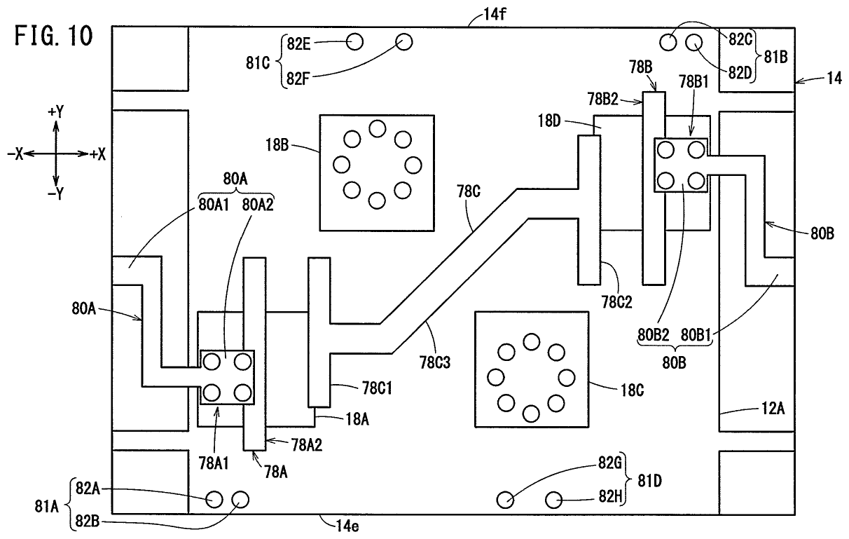

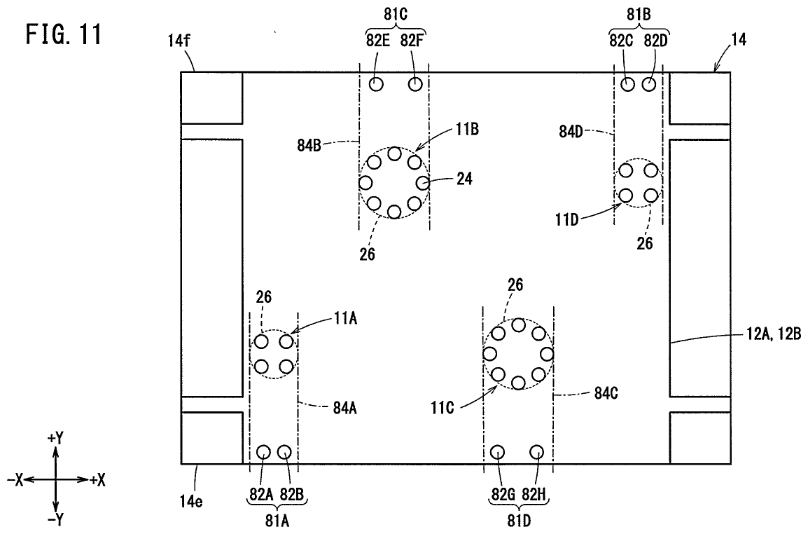

A filter according to an embodiment will be described with reference to the drawings. FIG. 1 is a perspective view showing the filter according to a present embodiment. FIG. 2 is a plan view showing the filter according to the present embodiment. FIG. 3A and FIG. 3B are cross-sectional views showing a portion of the filter according to the present embodiment. FIG. 4 and FIG. 5 are perspective views showing the filter according to the present embodiment. FIG. 6 is a plan view showing the filter according to the present embodiment. FIG. 7 is a perspective view showing the filter according to the present embodiment. FIG. 8 is a plan view showing the filter according to the present embodiment. FIG. 9 is a perspective view showing the filter according to the present embodiment. FIG. 10 and FIG. 11 are plan views showing the filter according to the present embodiment. For the sake of simplicity, portions of the constituent elements have been appropriately omitted from FIG. 1 to FIG. 11. In FIG. 1 to FIG. 11, an example is shown in which four resonators 11A to 11D are provided, however, the number of the resonators 11A to 11D is not necessarily limited to being four.

As shown in FIG. 1, a filter 10 according to the present embodiment is equipped with a dielectric substrate 14. The dielectric substrate 14 is formed, for example, in the shape of a rectangular parallelepiped, although the present embodiment is not necessarily limited to this feature. The dielectric substrate 14 is constituted by laminating (stacking in layers) a plurality of ceramic sheets (dielectric ceramic sheets).

The dielectric substrate 14 includes two main surfaces 14a and 14b, and four side surfaces 14c to 14f. The direction along a normal direction of the side surface 14c and the side surface 14d is defined as an X direction. More specifically, the normal direction of the side surfaces 14c and 14d is defined as the X direction. Stated otherwise, a longitudinal direction of the dielectric substrate 14 is defined as the X direction. The direction along the normal direction of the side surface 14e and the side surface 14f is defined as a Y direction. More specifically, the normal direction of the side surfaces 14e and 14f is defined as the Y direction. The direction along the normal direction of the main surfaces 14a and 14b is defined as a Z direction. More specifically, the normal direction of the main surfaces 14a and 14b is defined as the Z direction.

A shielding conductor (a lower portion shielding conductor) 12A is formed on a main surface 14b side from within the dielectric substrate 14. Specifically, the shielding conductor 12A is formed on a lower side of the dielectric substrate 14. A shielding conductor (an upper portion shielding conductor) 12B is formed on a main surface 14a side from within the dielectric substrate 14. Specifically, the shielding conductor (the upper portion shielding conductor) 12B is formed on an upper side of the dielectric substrate 14.

An input/output terminal (a first input/output terminal) 22A is formed on the side surface 14c of the dielectric substrate 14. An input/output terminal (a second input/output terminal) 22B is formed on the side surface 14d of the dielectric substrate 14. The input/output terminal 22A is coupled to the shielding conductor 12B via an input/output pattern 80A. Further, the input/output terminal 22B is coupled to the shielding conductor 12B via an input/output pattern 80B.

A shielding conductor 12Ca is formed on the side surface 14e of the dielectric substrate 14. A shielding conductor 12Cb is formed on the side surface 14f of the dielectric substrate 14. The shielding conductors 12Ca and 12Cb are formed in a plate shape. The shielding conductors 12Ca and 12Cb are formed along the longitudinal direction of the dielectric substrate 14.

Within the dielectric substrate 14, capacitor electrodes (strip lines) 18A to 18D are formed that face toward the shielding conductor 12A. Although the capacitor electrodes 18A to 18D are shown to be square shaped in FIG. 1, the shape of the capacitor electrodes 18A to 18D is not necessarily limited to being square shaped. For example, the shape of the capacitor electrodes 18A to 18D may be rectangular in shape. Moreover, when the individual capacitor electrodes are described without distinguishing therebetween, the reference numeral 18 will be used, and when the individual capacitor electrodes are described while distinguishing therebetween, the reference numerals 18A to 18D will be used.

Via electrode portions 20A to 20D are further formed inside the dielectric substrate 14. Moreover, when the individual via electrode portions are described without distinguishing therebetween, the reference numeral 20 will be used, and when the via electrode portions are described while distinguishing therebetween, the reference numerals 20A to 20D will be used.

The via electrode portions 20 are constituted by a plurality of via electrodes 24. The via electrodes 24 are embedded respectively into via holes that are formed in the dielectric substrate 14. The plurality of via electrodes 24 that make up the via electrode portion 20 are arranged along an imaginary ring 26 when viewed from an upper surface. More specifically, the plurality of via electrodes 24 that make up the via electrode portion 20, when viewed from the upper surface, are arranged along an imaginary circle. Since the via electrode portions 20 are formed by arranging the plurality of via electrodes 24 along the imaginary ring 26, the via electrode portions 20 can behave such as a large-diameter via electrode corresponding to the imaginary ring 26. Since the via electrode portions 20 are constituted by the plurality of via electrodes 24 each having a comparatively small diameter, the manufacturing process can be simplified. Further, since the via electrode portions 20 are constituted by the plurality of via electrodes 24 each having a comparatively small diameter, any variation in the diameters of the via electrode portions 20 can be reduced. Further, since the via electrode portions 20 are constituted by the plurality of via electrodes 24 each having a comparatively small diameter, the amount of material such as silver or the like that is embedded into the vias can be reduced, and thereby a reduction in cost can be achieved.

One end (a lower end) of each of the via electrode portions 20 is connected to the capacitor electrode 18. Another end (an upper end) of each of the via electrode portions 20 is connected to the shielding conductor 12B. In this manner, the via electrode portions 20 are formed from the capacitor electrodes 18 to the shielding conductor 12B.

A structural body 16A is constituted by the capacitor electrode 18A and the via electrode portion 20A. A structural body 16B is constituted by the capacitor electrode 18B and the via electrode portion 20B. A structural body 16C is constituted by the capacitor electrode 18C and the via electrode portion 20C. A structural body 16D is constituted by the capacitor electrode 18D and the via electrode portion 20D. Moreover, when the structural bodies are described without distinguishing therebetween, the reference numeral 16 will be used, and when the individual structural bodies are described while distinguishing therebetween, the reference numerals 16A to 16D will be used.

A plurality of resonators 11A to 11D, each respectively including one of the structural bodies 16, are provided in the filter 10. Moreover, when the individual resonators are described without distinguishing therebetween, the reference numeral 11 will be used, and when the individual resonators are described while distinguishing therebetween, the reference numerals 11A to 11D will be used.

The resonator 11A and the resonator 11B are arranged so as to be adjacent to each other. The resonator 11B and the resonator 11C are arranged so as to be adjacent to each other. The resonator 11C and the resonator 11D are arranged so as to be adjacent to each other. Each of the plurality of resonators 11 is provided with one of the via electrode portions 20.

As shown in FIG. 2, the via electrode portion 20A, the via electrode portion 20B, the via electrode portion 20C, and the via electrode portion 20D are shifted mutually from each other in the X direction. The position in the X direction of a center P2 of the via electrode portion 20B is between the position in the X direction of a center P1 of the via electrode portion 20A, and the position in the X direction of a center P3 of the via electrode portion 20C. The position in the X direction of the center P3 of the via electrode portion 20C is between the position in the X direction of the center P2 of the via electrode portion 20B, and the position in the X direction of a center P4 of the via electrode portion 20D.

The position in the Y direction of the center P1 of the via electrode portion 20A is equivalent to the position in the Y direction of the center P3 of the via electrode portion 20C. The position in the Y direction of the center P2 of the via electrode portion 20B is equivalent to the position in the Y direction of the center P4 of the via electrode portion 20D. The via electrode portion 20B and the via electrode portion 20D are shifted in the Y direction with respect to the via electrode portion 20A and the via electrode portion 20C. The via electrode portion 20A and the via electrode portion 20C are positioned on a side surface 14e side. Specifically, the distance between the shielding conductor 12Ca and the via electrode portions 20A and 20C is smaller than the distance between the shielding conductor 12Cb and the via electrode portions 20A and 20C. The via electrode portions 20B and 20D are positioned on a side surface 14f side. Specifically, the distance between the shielding conductor 12Cb and the via electrode portions 20B and 20D is smaller than the distance between the shielding conductor 12Ca and the via electrode portions 20B and 20D.

In this manner, according to the present embodiment, the position of the center P1 of the via electrode portion 20A and the position of the center P2 of the via electrode portion 20B are shifted mutually from each other not only in the X direction but also in the Y direction. Therefore, according to the present embodiment, without increasing the distance in the X direction between the via electrode portions 20A and 20B, the distance between the via electrode portions 20A and 20B can be made greater. Further, according to the present embodiment, the position of the center P2 of the via electrode portion 20B and the position of the center P3 of the via electrode portion 20C are shifted mutually from each other not only in the X direction but also in the Y direction. Therefore, according to the present embodiment, without increasing the distance in the X direction between the via electrode portions 20B and 20C, the distance between the via electrode portions 20B and 20C can be made greater. Further, according to the present embodiment, the position of the center P3 of the via electrode portion 20C and the position of the center P4 of the via electrode portion 20D are shifted mutually from each other not only in the X direction but also in the Y direction. Therefore, according to the present embodiment, without increasing the distance in the X direction between the via electrode portions 20C and 20D, the distance between the via electrode portions 20C and 20D can be made greater. In this manner, according to the present embodiment, without increasing the distance in the X direction between the adjacent resonators 11A to 11D, it is possible to reduce the degree of coupling between the adjacent resonators 11A to 11D. Therefore, according to the present embodiment, while keeping the size of the filter 10 small, it is possible to obtain a filter 10 having satisfactory characteristics.

From among the four via electrode portions 20A to 20D, the via electrode portion 20 that is closest in proximity to the input/output terminal 22A is the via electrode portion 20A. The distance in the X direction between the position of the center P1 of the via electrode portion 20A and the position of the input/output terminal 22A is smaller than the distance in the X direction between the position of the center P2 of the via electrode portion 20B and the position of the input/output terminal 22A. The distance in the Y direction between the position of the center P1 of the via electrode portion 20A and the position of the input/output terminal 22A is equivalent to the distance in the Y direction between the position of the center P2 of the via electrode portion 20B and the position of the input/output terminal 22A.

From among the four via electrode portions 20A to 20D, the via electrode portion 20 that is closest in proximity to the input/output terminal 22B is the via electrode portion 20D. The distance in the X direction between the position of the center P4 of the via electrode portion 20D and the position of the input/output terminal 22B is smaller than the distance in the X direction between the position of the center P3 of the via electrode portion 20C and the position of the input/output terminal 22B. The distance in the Y direction between the position of the center P4 of the via electrode portion 20D and the position of the input/output terminal 22B is equivalent to the distance in the Y direction between the position of the center P3 of the via electrode portion 20C and the position of the input/output terminal 22B.

The resonators 11A to 11D are arranged at positions that are point symmetrical, with a center C of the dielectric substrate 14 as viewed in plan serving as the center of symmetry. Specifically, the resonator 11A and the resonator 11D are arranged at positions that are point symmetrical, with the center C of the dielectric substrate 14 as viewed in plan serving as the center of symmetry. Further, the resonator 11B and the resonator 11C are also arranged at positions that are point symmetrical, with the center C of the dielectric substrate 14 as viewed in plan serving as the center of symmetry. In the present embodiment, the feature in which the resonators 11A to 11D are arranged in point symmetry is in order to obtain satisfactory frequency characteristics.

The positions in the Y direction of the center P1 of the via electrode portion 20A and the center P3 of the via electrode portion 20C are positioned on a side surface 14e side with respect to the position in the Y direction of the center C of the dielectric substrate 14. The positions in the Y direction of the center P2 of the via electrode portion 20B and the center P4 of the via electrode portion 20D are positioned on a side surface 14f side with respect to the position in the Y direction of the center C of the dielectric substrate 14. The positions in the Y direction of the center of the input/output terminals 22A and the center of the input/output terminal 22B are set to be equivalent to the position in the Y direction of the center C of the dielectric substrate 14.

As shown in FIG. 5, coupling capacitance electrodes (plate electrodes) 70A to 70F are formed within the dielectric substrate 14. The coupling capacitance electrode 70A is provided on the resonator 11A. The coupling capacitance electrode 70B is provided on the resonator 11D. The coupling capacitance electrode 70C is provided on the resonator 11B. The coupling capacitance electrode 70D is provided on the resonator 11C. The coupling capacitance electrodes 70E and 70F are provided in proximity to the center C (refer to FIG. 2) of the dielectric substrate 14 as viewed in plan. The coupling capacitance electrodes 70A to 70F are formed in the same layer. Stated otherwise, the coupling capacitance electrodes 70A to 70F are formed on the same ceramic sheet (not shown). When the individual coupling capacitance electrodes are described without distinguishing therebetween, the reference numeral 70 will be used, and when the individual coupling capacitance electrodes are described while distinguishing therebetween, the reference numerals 70A to 70F will be used. One or more non-illustrated ceramic sheets exist between the coupling capacitance electrodes 70 and the capacitor electrodes 18. The coupling capacitance electrodes 70 can be formed, for example, by a printing method.

The coupling capacitance electrodes 70 are arranged at positions that are point symmetrical, with the center C of the dielectric substrate 14 as viewed in plan serving as the center of symmetry. Specifically, the coupling capacitance electrode 70A and the coupling capacitance electrode 70B are arranged at positions that are point symmetrical, with the center C of the dielectric substrate 14 as viewed in plan serving as the center of symmetry. Further, the coupling capacitance electrode 700 and the coupling capacitance electrode 70D are also arranged at positions that are point symmetrical, with the center C of the dielectric substrate 14 as viewed in plan serving as the center of symmetry. Further, the coupling capacitance electrode 70E and the coupling capacitance electrode 70F are also arranged at positions that are point symmetrical, with the center C of the dielectric substrate 14 as viewed in plan serving as the center of symmetry. In the present embodiment, the feature in which the coupling capacitance electrodes 70 are arranged in point symmetry is in order to obtain satisfactory frequency characteristics.

The coupling capacitance electrode 70A is connected to the via electrode portion 20A. A lower surface of the coupling capacitance electrode 70A is connected to an upper surface of the capacitor electrode 18A via a part of the via electrode portion 20A.

The coupling capacitance electrode 70B is connected to the via electrode portion 20D. A lower surface of the coupling capacitance electrode 70B is connected to an upper surface of the capacitor electrode 18D via a part of the via electrode portion 20D.

The coupling capacitance electrode 70C is connected to the via electrode portion 20B. A lower surface of the coupling capacitance electrode 70C is connected to an upper surface of the capacitor electrode 18B via a part of the via electrode portion 20B.

The coupling capacitance electrode 70D is connected to the via electrode portion 20C. A lower surface of the coupling capacitance electrode 70D is connected to an upper surface of the capacitor electrode 18C via a part of the via electrode portion 20C.

As shown in FIG. 6, the coupling capacitance electrode 70A includes partial patterns (electrode patterns) 70A1 to 70A3. The partial pattern 70A1 is connected to the via electrode portion 20A. One end of the partial pattern 70A2 is connected to the partial pattern 70A1. The partial pattern 70A2 projects out in the +X direction. One end of the partial pattern 70A3 is connected to the partial pattern 70A1. The partial pattern 70A3 projects out in the +Y direction.

The coupling capacitance electrode 70B includes partial patterns 70B1 to 70B3. The partial pattern 70B1 is connected to the via electrode portion 20D. One end of the partial pattern 70B2 is connected to the partial pattern 70B1. The partial pattern 70B2 projects out in the −X direction. One end of the partial pattern 70B3 is connected to the partial pattern 70B1. The partial pattern 70B3 projects out in the −Y direction.

The coupling capacitance electrode 70C includes partial patterns 70C1 to 70C3. The partial pattern 70C1 is connected to the via electrode portion 20B. One end of the partial pattern 70C2 is connected to the partial pattern 70C1. The partial pattern 70C2 projects out in the −X direction. One end of the partial pattern 70C3 is connected to the partial pattern 70C1. The partial pattern 70C3 projects out in the +X direction.

The coupling capacitance electrode 70D includes partial patterns 70D1 to 70D3. The partial pattern 70D1 is connected to the via electrode portion 20C. One end of the partial pattern 70D2 is connected to the partial pattern 7001. The partial pattern 70D2 projects out in the +X direction. One end of the partial pattern 70D3 is connected to the partial pattern 70D1. The partial pattern 70D3 projects out in the −X direction.

The position of the coupling capacitance electrode 70E in the Y direction is between the positions in the Y direction of the coupling capacitance electrodes 70A and 70D, and the positions in the Y direction of the coupling capacitance electrodes 70B and 70C. The position of the coupling capacitance electrode 70E in the X direction is between the position in the X direction of the partial pattern 70A3 that is provided on the coupling capacitance electrode 70A, and the position in the X direction of the coupling capacitance electrode 70F. The coupling capacitance electrode 70E is connected to the coupling capacitance electrode 70C.

The position of the coupling capacitance electrode 70F in the Y direction is between the positions in the Y direction of the coupling capacitance electrodes 70A and 70D, and the positions in the Y direction of the coupling capacitance electrodes 70B and 70C. The position of the coupling capacitance electrode 70F in the X direction is between the position in the X direction of the partial pattern 70B3 that is provided on the coupling capacitance electrode 70B, and the position in the X direction of the coupling capacitance electrode 70E. The coupling capacitance electrode 70F is connected to the coupling capacitance electrode 70D.

As shown in FIG. 5, coupling capacitance electrodes (plate electrodes) 72A to 72E are further formed within the dielectric substrate 14. The coupling capacitance electrodes 72A to 72E are formed in the same layer. Stated otherwise, the coupling capacitance electrodes 72A to 72E are formed on the same ceramic sheet (not shown). When the individual coupling capacitance electrodes are described without distinguishing therebetween, the reference numeral 72 will be used, and when the individual coupling capacitance electrodes are described while distinguishing therebetween, the reference numerals 72A to 72F will be used. One or more non-illustrated ceramic sheets exist between the coupling capacitance electrodes 72 and the coupling capacitance electrodes 70. The coupling capacitance electrodes 72 can be formed, for example, by a printing method.

The coupling capacitance electrodes 72 are arranged at positions that are point symmetrical, with the center C of the dielectric substrate 14 as viewed in plan serving as the center of symmetry (refer to FIG. 2). Specifically, the coupling capacitance electrode 72A and the coupling capacitance electrode 72B are arranged at positions that are point symmetrical, with the center C of the dielectric substrate 14 as viewed in plan serving as the center of symmetry. The coupling capacitance electrode 72C and the coupling capacitance electrode 72D are also arranged at positions that are point symmetrical, with the center C of the dielectric substrate 14 as viewed in plan serving as the center of symmetry. In the present embodiment, the feature in which the coupling capacitance electrodes 72 are arranged in point symmetry is in order to obtain satisfactory frequency characteristics.

As shown in FIG. 6, the longitudinal direction of the coupling capacitance electrode 72A is the Y direction. One end of the coupling capacitance electrode 72A overlaps with the coupling capacitance electrode 70A as viewed in plan. More specifically, the one end of the coupling capacitance electrode 72A overlaps with the partial pattern 70A3 as viewed in plan. Another end of the coupling capacitance electrode 72A overlaps with the coupling capacitance electrode 70C as viewed in plan. More specifically, the other end of the coupling capacitance electrode 72A overlaps with the partial pattern 70C2 as viewed in plan. A capacitive coupling structure 71A is constituted by the coupling capacitance electrode 70A, the coupling capacitance electrode 72A, and the coupling capacitance electrode 70C.

The longitudinal direction of the coupling capacitance electrode 72B is the Y direction. One end of the coupling capacitance electrode 72B overlaps with the coupling capacitance electrode 70D as viewed in plan. More specifically, the one end of the coupling capacitance electrode 72B overlaps with the partial pattern 70D2 as viewed in plan. Another end of the coupling capacitance electrode 72B overlaps with the coupling capacitance electrode 70B as viewed in plan. More specifically, the other end of the coupling capacitance electrode 72B overlaps with the partial pattern 70B3 as viewed in plan. A capacitive coupling structure 71B is constituted by the coupling capacitance electrode 70B, the coupling capacitance electrode 72B, and the coupling capacitance electrode 70D.

The longitudinal direction of the coupling capacitance electrode 72C is the X direction. One end of the coupling capacitance electrode 72C overlaps with the coupling capacitance electrode 70A as viewed in plan. More specifically, the one end of the coupling capacitance electrode 72C overlaps with the partial pattern 70A2 as viewed in plan. Another end of the coupling capacitance electrode 72C overlaps with the coupling capacitance electrode 70D as viewed in plan. More specifically, the other end of the coupling capacitance electrode 72C overlaps with the partial pattern 70D3 as viewed in plan. A capacitive coupling structure 71C is constituted by the coupling capacitance electrode 70A, the coupling capacitance electrode 72C, and the coupling capacitance electrode 70D. The via electrode portion 20A and the via electrode portion 20C are positioned on extending regions of the coupling capacitance electrode 72C. Specifically, the via electrode portion 20A is positioned on the extending region of one end of the coupling capacitance electrode 72C, and the via electrode portion 20C is positioned on the extending region of another end of the coupling capacitance electrode 72C.

The longitudinal direction of the coupling capacitance electrode 72D is the X direction. One end of the coupling capacitance electrode 72D overlaps with the coupling capacitance electrode 70B as viewed in plan. More specifically, the one end of the coupling capacitance electrode 72D overlaps with the partial pattern 70B2 as viewed in plan. Another end of the coupling capacitance electrode 72D overlaps with the coupling capacitance electrode 70C as viewed in plan. More specifically, the other end of the coupling capacitance electrode 72D overlaps with the partial pattern 70C3 as viewed in plan. A capacitive coupling structure 71D is constituted by the coupling capacitance electrode 70B, the coupling capacitance electrode 72D, and the coupling capacitance electrode 70C. The via electrode portion 20B and the via electrode portion 20D are positioned on extending regions of the coupling capacitance electrode 72D. Specifically, the via electrode portion 20D is positioned on then extending region of one end of the coupling capacitance electrode 72D, and the via electrode portion 20B is positioned on the extending region of another end of the coupling capacitance electrode 72C.

The longitudinal direction of the coupling capacitance electrode 72E is the X direction. One end of the coupling capacitance electrode 72E overlaps with the coupling capacitance electrode 70E as viewed in plan. Another end of the coupling capacitance electrode 72E overlaps with the coupling capacitance electrode 70F as viewed in plan.

An inter-electrode distance d1 (refer to FIG. 3A), which is a distance between the coupling capacitance electrode 72 and the coupling capacitance electrode 70 in the thickness direction of the coupling capacitance electrode 72, for example, is on the order of 0.12 mm, although the present invention is not necessarily limited to this feature. The inter-electrode distance d1, for example, may be 0.06 mm. The inter-electrode distance d1 is not necessarily limited to this value.

A dimension W12 of the coupling capacitance electrode 72A in the widthwise direction (the X direction) of the coupling capacitance electrode 72A is smaller than a dimension W11 of the partial pattern 70A3 in the widthwise direction of the coupling capacitance electrode 72A. Specifically, the dimension W12 of the coupling capacitance electrode 72A in the X direction is smaller than the dimension W11 of the partial pattern 70A3 in the X direction. On both sides of a region (a portion) 73A1 in which the coupling capacitance electrode 72A and the partial pattern 70A3 overlap as viewed in plan, there exist regions (portions) 73A2 and 73A3 in which the coupling capacitance electrode 72A does not overlap with the partial pattern 70A3. The region 73A2 is positioned on a −X side with respect to the region 73A1. The region 73A3 is positioned on a +X side with respect to the region 73A1. The dimension W11 of the partial pattern 70A3 in the widthwise direction of the coupling capacitance electrode 72A is set, for example, to 0.54 mm. The dimension W12 of the coupling capacitance electrode 72A in the widthwise direction of the coupling capacitance electrode 72A is set, for example, to 0.18 mm.

The dimension W12 of the coupling capacitance electrode 72A in the widthwise direction of the coupling capacitance electrode 72A is smaller than the dimension of the partial pattern 70C2 in the widthwise direction of the coupling capacitance electrode 72A. Specifically, the dimension W12 of the coupling capacitance electrode 72A in the X direction is smaller than the dimension of the partial pattern 70C2 in the X direction. On both sides of a region 73B1 in which the coupling capacitance electrode 72A and the partial pattern 70C2 overlap as viewed in plan, there exist regions 73B2 and 73B3 in which the coupling capacitance electrode 72A does not overlap with the partial pattern 70C2. The region 73B2 is positioned on a −X side with respect to the region 73B1. The region 73B3 is positioned on a +X side with respect to the region 73B1.

The dimension W12 of the coupling capacitance electrode 72B in the widthwise direction (the X direction) of the coupling capacitance electrode 72B is smaller than the dimension W11 of the partial pattern 70B3 in the widthwise direction of the coupling capacitance electrode 72B. Specifically, the dimension W12 of the coupling capacitance electrode 72B in the X direction is smaller than the dimension W11 of the partial pattern 70B3 in the X direction. On both sides of a region 73C1 in which the coupling capacitance electrode 72B and the partial pattern 70B3 overlap as viewed in plan, there exist regions 73C2 and 73C3 in which the coupling capacitance electrode 72B does not overlap with the partial pattern 70B3. The region 73C2 is positioned on a −X side with respect to the region 73C1. The region 73C3 is positioned on a +X side with respect to the region 73C1. The dimension W11 of the partial pattern 70B3 in the widthwise direction of the coupling capacitance electrode 72B is set, for example, to 0.54 mm. The dimension W12 of the coupling capacitance electrode 72B in the widthwise direction of the coupling capacitance electrode 72B is set, for example, to 0.18 mm.

The dimension W12 of the coupling capacitance electrode 72B in the widthwise direction of the coupling capacitance electrode 72B is smaller than the dimension W11 of the partial pattern 70D2 in the widthwise direction of the coupling capacitance electrode 72B. Specifically, the dimension W12 of the coupling capacitance electrode 72B in the X direction is smaller than the dimension W11 of the partial pattern 70D2 in the X direction. On both sides of a region 73D1 in which the coupling capacitance electrode 72B and the partial pattern 70D2 overlap as viewed in plan, there exist regions 73D2 and 73D3 in which the coupling capacitance electrode 72B does not overlap with the partial pattern 70D2. The region 73D2 is positioned on a −X side with respect to the region 73D1. The region 73D3 is positioned on a +X side with respect to the region 73D1.

A dimension W22 of the coupling capacitance electrode 72C in the widthwise direction (the Y direction) of the coupling capacitance electrode 72C is smaller than a dimension W21 of the partial pattern 70A2 in the widthwise direction of the coupling capacitance electrode 72C. Specifically, the dimension W22 of the coupling capacitance electrode 72C in the Y direction is smaller than the dimension W21 of the partial pattern 70A2 in the Y direction. On both sides of a region 73E1 in which the coupling capacitance electrode 72C and the partial pattern 70A2 overlap as viewed in plan, there exist regions 73E2 and 73E3 in which the coupling capacitance electrode 72C does not overlap with the partial pattern 70A2. The region 73E2 is positioned on a −Y side with respect to the region 73E1. The region 73E3 is positioned on a +Y side with respect to the region 73E1. The dimension W21 of the partial pattern 70A2 in the widthwise direction of the coupling capacitance electrode 72C is set, for example, to 0.56 mm. The dimension W22 of the coupling capacitance electrode 72C in the widthwise direction of the coupling capacitance electrode 72C is set, for example, to 0.34 mm.

The dimension W22 of the coupling capacitance electrode 72C in the widthwise direction of the coupling capacitance electrode 72C is smaller than the dimension W21 of the partial pattern 70D3 in the widthwise direction of the coupling capacitance electrode 72C. Specifically, the dimension W22 of the coupling capacitance electrode 72C in the Y direction is smaller than the dimension W21 of the partial pattern 70D3 in the Y direction. On both sides of a region 73F1 in which the coupling capacitance electrode 72C and the partial pattern 70D3 overlap as viewed in plan, there exist regions 73F2 and 73F3 in which the coupling capacitance electrode 72C does not overlap with the partial pattern 70D3. The region 73F2 is positioned on a −Y side with respect to the region 73F1. The region 73F3 is positioned on a +Y side with respect to the region 73F1. The dimension W21 of the partial pattern 70D3 in the widthwise direction of the coupling capacitance electrode 72C is set, for example, to 0.56 mm.

The dimension W22 of the coupling capacitance electrode 72D in the widthwise direction (the Y direction) of the coupling capacitance electrode 72D is smaller than the dimension W21 of the partial pattern 70C3 in the widthwise direction of the coupling capacitance electrode 72D. Specifically, the dimension W22 of the coupling capacitance electrode 72D in the Y direction is smaller than the dimension W21 of the partial pattern 70C3 in the Y direction. On both sides of a region 73G1 in which the coupling capacitance electrode 72D and the partial pattern 70C3 overlap as viewed in plan, there exist regions 73G2 and 73G3 in which the coupling capacitance electrode 72D does not overlap with the partial pattern 70C3. The region 73G2 is positioned on a −Y side with respect to the region 73G1. The region 73G3 is positioned on a +Y side with respect to the region 73G1. The dimension W21 of the partial pattern 70C3 in the widthwise direction of the coupling capacitance electrode 72D is set, for example, to 0.56 mm. The dimension W22 of the coupling capacitance electrode 72D in the widthwise direction of the coupling capacitance electrode 72D is set, for example, to 0.34 mm.

The dimension W22 of the coupling capacitance electrode 72D in the widthwise direction of the coupling capacitance electrode 72D is smaller than the dimension W21 of the partial pattern 70B2 in the widthwise direction of the coupling capacitance electrode 72D. Specifically, the dimension W22 of the coupling capacitance electrode 72D in the Y direction is smaller than the dimension W21 of the partial pattern 70B2 in the Y direction. On both sides of a region 73H1 in which the coupling capacitance electrode 72D and the partial pattern 70B2 overlap as viewed in plan, there exist regions 73H2 and 73H3 in which the coupling capacitance electrode 72D does not overlap with the partial pattern 70B2. The region 73H2 is positioned on a −Y side with respect to the region 73H1. The region 73H3 is positioned on a +Y side with respect to the region 73H1. The dimension W21 of the partial pattern 70B2 in the widthwise direction of the coupling capacitance electrode 72D is set, for example, to 0.56 mm.

A dimensional difference ΔW1, which is a value obtained by subtracting the dimension W12 of the coupling capacitance electrodes 72A and 72B in the widthwise direction of the coupling capacitance electrodes 72A and 72B from the dimension W11 of the partial patterns 70A3 and 70B3 in the widthwise direction of the coupling capacitance electrodes 72A and 72B, is preferably greater than or equal to 1.4 times the inter-electrode distance d1. It is more preferable for the dimensional difference ΔW1, and specifically the dimensional difference (W11-W12), to be greater than or equal to 2.6 times the inter-electrode distance d1. According to the present embodiment, the dimensional difference ΔW1 is set to three times the inter-electrode distance d1.

In order for the dimensional difference ΔW1 to be set to be comparatively large in the manner described above, a dimension L1 in the X direction of the regions 73A2, 73A3, 73B2, 73B3, 73C2, 73C3, 73D2, and 73D3 is comparatively large. In the case that the dimension W11 of the partial patterns 70A3 and 70B3 in the widthwise direction of the coupling capacitance electrodes 72A and 72B is 0.54 mm, and the dimension W12 of the coupling capacitance electrodes 72A and 72B in the widthwise direction of the coupling capacitance electrodes 72A and 72B is 0.18 mm, the dimensional difference ΔW1 is 0.36 mm. In the case that the dimensional difference ΔW1 is 0.36 mm, the dimension L1 is 0.18 mm. In this case, the dimension L1, for example, is 1.5 times the inter-electrode distance d1. In this manner, in the case that the dimensional difference ΔW1 is three times the inter-electrode distance d1, the dimension L1, for example, is 1.5 times the inter-electrode distance d1.

A dimensional difference ΔW2, which is a value obtained by subtracting the dimension W22 of the coupling capacitance electrodes 72C and 72D in the widthwise direction of the coupling capacitance electrodes 72C and 72D from the dimension W21 of the partial patterns 70A2, 70B2, 70C3, and 70D3 in the widthwise direction of the coupling capacitance electrodes 72C and 72D, is preferably greater than or equal to 1.4 times the inter-electrode distance d1. According to the present embodiment, the dimensional difference ΔW2, and specifically the dimensional difference (W21-W22), is set to 1.84 times the inter-electrode distance d1.

Since the dimensional difference ΔW2 is set to be comparatively large in the manner described above, a dimension L2 in the Y direction of the regions 73E2, 73E3, 73F2, 73F3, 73G2, 73G3, 73H2, and 73H3 is comparatively large. In the case that the dimension W21 of the partial patterns 70A2, 70B2, 70C3, and 70D3 in the widthwise direction of the coupling capacitance electrodes 72C and 72D is 0.56 mm, and the dimension W22 of the coupling capacitance electrodes 72C and 72D in the widthwise direction of the coupling capacitance electrodes 72C and 72D is 0.34 mm, the dimensional difference ΔW2 is 0.22 mm. In the case that the dimensional difference ΔW2 is 0.22 mm, the dimension L2 is 0.11 mm. In this case, the dimension L2, for example, is 0.92 times the inter-electrode distance d1. In this manner, in the case that the dimensional difference ΔW2 is 1.84 times the inter-electrode distance d1, the dimension L2, for example, is 0.92 times the inter-electrode distance d1.

A maximum positional deviation at the time of manufacturing, for example, is on the order of 0.03 mm. In the case that the maximum positional deviation at the time of manufacturing is 0.03 mm, the dimensions L1 and L2 can be set, for example, to 0.03 mm. In contrast thereto, according to the present embodiment, the dimensions L1 and L2 are set to be comparatively large. In the present embodiment, the dimensions L1 and L2 are set to be comparatively large for the following reason. Specifically, in the case that the dimensions L1 and L2 are comparatively small, if a certain degree of positional shifting occurs at the time of manufacturing, the electrostatic capacitance of the capacitive coupling structures 71A to 71D will vary significantly. When the capacitance of the capacitive coupling structures 71A to 71D varies significantly, satisfactory filter characteristics cannot be obtained. In the case that the dimensions L1 and L2 are comparatively large, then even if a certain degree of positional shifting occurs at the time of manufacturing, the electrostatic capacitance of the capacitive coupling structures 71A to 71D does not vary significantly. Due to such a reason, according to the present embodiment, the dimensions L1 and L2 are set to be comparatively large.

The reason why the dimension L2 is set to be smaller than the dimension L1 is as follows. Specifically, from the standpoint of suppressing the variation in the electrostatic capacitance of the capacitive coupling structure 71C caused by positional shifting at the time of manufacturing, it is preferable for the dimension L2 to be comparatively large. In the case that the dimension L2 is set to be comparatively large, then in order to guarantee an area for the regions 73E1, 73F1, 73H1, and 73H1 in which the coupling capacitance electrodes 72C and 72D and the partial patterns 70A2, 70D3, 70B2, and 70C3 overlap as viewed in plan, it is preferable for the dimension in the X direction of the coupling capacitance electrodes 72C and 72D to be made large. However, in the case that the dimension of the coupling capacitance electrode 72C in the X direction is made large, the distance in the X direction between the coupling capacitance electrode 72C and the via electrode portion 20A becomes short, and the distance in the X direction between the coupling capacitance electrode 72C and the via electrode portion 20C becomes short. Further, in the case that the dimension of the coupling capacitance electrode 72D in the X direction is made large, the distance in the X direction between the coupling capacitance electrode 72D and the via electrode portion 20B becomes short, and the distance in the X direction between the coupling capacitance electrode 72D and the via electrode portion 20D becomes short. When the distance in the X direction between the coupling capacitance electrode 72C and the via electrode portion 20A becomes short, and the distance in the X direction between the coupling capacitance electrode 72C and the via electrode portion 20C becomes short, a concern is brought about in that an adverse influence may occur in the filter characteristics. Further, when the distance in the X direction between the coupling capacitance electrode 72D and the via electrode portion 20B becomes short, and the distance in the X direction between the coupling capacitance electrode 72D and the via electrode portion 20D becomes short, a concern is brought about in that an adverse influence may occur in the filter characteristics. On the other hand, none of the via electrode portions 20 is positioned on the extending region of at least one end of each of the coupling capacitance electrodes 72A and 72B. The via electrode portion 20B is arranged at a position that is spaced apart in the +X direction with respect to the coupling capacitance electrode 72A. Therefore, even if the coupling capacitance electrode 72A is extended in the +Y direction, the distance between the coupling capacitance electrode 72A and the via electrode portion 20B does not become small. Further, the via electrode portion 20C is arranged at a position that is spaced apart in the −X direction with respect to the coupling capacitance electrode 72B. Therefore, even if the coupling capacitance electrode 72B is extended in the −Y direction, the distance between the coupling capacitance electrode 72B and the via electrode portion 20C does not become small. No particular problem arises even if the coupling capacitance electrode 72A is extended in the +Y direction. Further, no particular problem arises even if the coupling capacitance electrode 72B is extended in the −Y direction. Due to such a reason, the dimension L2 is set to be smaller than the dimension L1.

The dimension of the coupling capacitance electrode 72E in the widthwise direction of the coupling capacitance electrode 72E is smaller than the dimension of the coupling capacitance electrode 70E in the widthwise direction of the coupling capacitance electrode 72E. Specifically, the dimension of the coupling capacitance electrode 72E in the Y direction is smaller than the dimension of the coupling capacitance electrode 70E in the Y direction. The dimension of the coupling capacitance electrode 70E in the widthwise direction of the coupling capacitance electrode 72E is set, for example, to 0.5 mm. The dimension of the coupling capacitance electrode 72E in the widthwise direction of the coupling capacitance electrode 72E is set, for example, to 0.29 mm.

The dimension of the coupling capacitance electrode 72E in the widthwise direction of the coupling capacitance electrode 72E is smaller than the dimension of the coupling capacitance electrode 70F in the widthwise direction of the coupling capacitance electrode 72E. Specifically, the dimension of the coupling capacitance electrode 72E in the Y direction is smaller than the dimension of the coupling capacitance electrode 70F in the Y direction. The dimension of the coupling capacitance electrode 70F in the widthwise direction of the coupling capacitance electrode 72E is set, for example, to 0.5 mm.

A dimensional difference ΔW3, which is a value obtained by subtracting a dimension W32 of the coupling capacitance electrode 72E in the widthwise direction of the coupling capacitance electrode 72E from a dimension W31 of the coupling capacitance electrodes 70E and 70F in the widthwise direction of the coupling capacitance electrode 72E, is preferably greater than or equal to 1.4 times the inter-electrode distance d1. According to the present embodiment, the dimensional difference ΔW3, and specifically the dimensional difference (W31−W32), is set to 1.75 times the inter-electrode distance d1.

As shown in FIG. 5, coupling capacitance electrodes (plate electrodes) 74A and 74B are formed within the dielectric substrate 14. The coupling capacitance electrodes 74A and 74B are formed in the same layer. Stated otherwise, the coupling capacitance electrodes 74A and 74B are formed on the same ceramic sheet (not shown). When the individual coupling capacitance electrodes are described without distinguishing therebetween, the reference numeral 74 will be used, and when the individual coupling capacitance electrodes are described while distinguishing therebetween, the reference numerals 74A and 74B will be used. One or more non-illustrated ceramic sheets exist between the coupling capacitance electrodes 72 and the coupling capacitance electrodes 74.

The coupling capacitance electrodes 74 are arranged at positions that are point symmetrical, with the center C of the dielectric substrate 14 (refer to FIG. 2) as viewed in plan serving as the center of symmetry. The coupling capacitance electrode 74A and the coupling capacitance electrode 74B are arranged at positions that are point symmetrical, with the center C of the dielectric substrate 14 as viewed in plan serving as the center of symmetry. In the present embodiment, the feature in which the coupling capacitance electrodes 74 are disposed in point symmetry is in order to obtain satisfactory frequency characteristics.

As shown in FIG. 6, the coupling capacitance electrode 74A includes partial patterns (electrode patterns) 74A1 to 74A3. The partial pattern 74A1 is connected to the via electrode portion 20B. The partial pattern 74A3 is positioned on a −Y side with respect to the partial pattern 74A1. The partial pattern 74A3 is connected to the partial pattern 74A1 via the partial pattern 74A2. The partial pattern 74A3 overlaps with the coupling capacitance electrode 70E as viewed in plan. The size of the partial pattern 74A3 is equivalent to the size of the coupling capacitance electrode 70E. One end of the coupling capacitance electrode 72E is sandwiched between the coupling capacitance electrode 70E and the partial pattern 74A3.

The coupling capacitance electrode 74B includes partial patterns 74B1 to 74B3. The partial pattern 74B1 is connected to the via electrode portion 20C. The partial pattern 74B3 is positioned on a +Y side with respect to the partial pattern 74B1. The partial pattern 74B3 is connected to the partial pattern 74B1 via the partial pattern 74B2. The partial pattern 74B3 overlaps with the coupling capacitance electrode 70F as viewed in plan. The size of the partial pattern 74B3 is equivalent to the size of the coupling capacitance electrode 70F. The other end of the coupling capacitance electrode 72E is sandwiched between the coupling capacitance electrode 70F and the partial pattern 74B3. The coupling capacitance electrode 70E, the coupling capacitance electrode 70F, the coupling capacitance electrode 72E, the coupling capacitance electrode 74A, and the coupling capacitance electrode 74B form a capacitive coupling structure 71E.

As shown in FIG. 7, coupling capacitance electrodes (comb-tooth or interdigitated electrodes) 76A to 76D are formed within the dielectric substrate 14. The coupling capacitance electrodes 76A to 76D are formed in the same layer. Stated otherwise, the coupling capacitance electrodes 76A to 76D are formed on the same ceramic sheet (not shown). When the individual coupling capacitance electrodes are described without distinguishing therebetween, the reference numeral 76 will be used, and when the individual coupling capacitance electrodes are described while distinguishing therebetween, the reference numerals 76A to 76D will be used. One or more non-illustrated ceramic sheets exist between the coupling capacitance electrodes 74 (refer to FIG. 5) and the coupling capacitance electrodes 76.

The coupling capacitance electrodes 76 are arranged at positions that are point symmetrical, with the center C of the dielectric substrate 14 (refer to FIG. 2) as viewed in plan serving as the center of symmetry. Specifically, the coupling capacitance electrode 76A and the coupling capacitance electrode 76B are arranged at positions that are point symmetrical, with the center C of the dielectric substrate 14 as viewed in plan serving as the center of symmetry. Further, the coupling capacitance electrode 76C and the coupling capacitance electrode 76D are disposed at positions that are point symmetrical, with the center C of the dielectric substrate 14 as viewed in plan serving as the center of symmetry. In the present embodiment, the feature in which the coupling capacitance electrodes 76 are disposed in point symmetry is in order to obtain satisfactory frequency characteristics.

As shown in FIG. 8, the coupling capacitance electrode 76A includes partial patterns (electrode patterns) 76A1 to 76A4. The partial pattern 76A1 is connected to the via electrode portion 20A. A longitudinal direction of the partial pattern 76A2 is the X direction. One end of the partial pattern 76A2 is connected to the partial pattern 76A1. The partial pattern 76A2 projects out in the +X direction. One end of the partial pattern 76A3 is connected to another end of the partial pattern 76A2. A longitudinal direction of the partial pattern 76A3 is the Y direction. The partial pattern 76A3 projects out in the −Y direction. Specifically, the partial pattern 76A3 projects out toward the side surface 14e. One end of the partial pattern 76A4 is connected to the partial pattern 76A1. A longitudinal direction of the partial pattern 76A4 is the Y direction. The partial pattern 76A4 projects out in the +Y direction. The partial pattern 76A4 projects out so as to follow along the longitudinal direction of the partial pattern 76A3.

The coupling capacitance electrode 76B includes partial patterns 76B1 to 76B4. The partial pattern 76B1 is connected to the via electrode portion 20D. A longitudinal direction of the partial pattern 76B2 is the X direction. One end of the partial pattern 76B2 is connected to the partial pattern 76B1. The partial pattern 76B2 projects out in the −X direction. One end of the partial pattern 76B3 is connected to the partial pattern 76B2. A longitudinal direction of the partial pattern 76B3 is the Y direction. The partial pattern 76B3 projects out in the +Y direction. The partial pattern 76B3 projects out so as to follow along the longitudinal direction of the partial pattern 76A3. One end of the partial pattern 76B4 is connected to the partial pattern 76B1. A longitudinal direction of the partial pattern 76B4 is the Y direction. The partial pattern 76B4 projects out in the −Y direction. The partial pattern 76B4 projects out so as to follow along the longitudinal direction of the partial pattern 76A3.

The coupling capacitance electrode 76C includes partial patterns 76C1 to 76C6. The partial pattern 76C1 is connected to the via electrode portion 20B. A longitudinal direction of the partial pattern 76C2 is the X direction. One end of the partial pattern 76C2 is connected to the partial pattern 76C1. The partial pattern 76C2 projects out in the −X direction. One end of the partial pattern 76C3 is connected to another end of the partial pattern 76C2. A longitudinal direction of the partial pattern 76C3 is the Y direction. The partial pattern 76C3 projects out in the −Y direction. The partial pattern 76C3 projects out so as to follow along the longitudinal direction of the partial pattern 76A3. One end of the partial pattern 76C4 is connected to the partial pattern 76C1. A longitudinal direction of the partial pattern 76C4 is the Y direction. The partial pattern 76C4 projects out in the −Y direction. The partial pattern 76C4 projects out so as to follow along the longitudinal direction of the partial pattern 76A3. A longitudinal direction of the partial pattern 76C5 is the X direction. One end of the partial pattern 76C5 is connected to the partial pattern 76C1. The partial pattern 76C5 projects out in the +X direction. One end of the partial pattern 76C6 is connected to another end of the partial pattern 76C5. A longitudinal direction of the partial pattern 76C6 is the Y direction. The partial pattern 76C6 projects out in the +Y direction. Specifically, the partial pattern 76C6 projects out toward the side surface 14f. The partial pattern 76C6 projects out so as to follow along the longitudinal direction of the partial pattern 76A3.

The coupling capacitance electrode 76D includes partial patterns 76D1 to 7606. The partial pattern 76D1 is connected to the via electrode portion 20C. A longitudinal direction of the partial pattern 76D2 is the X direction. One end of the partial pattern 76D2 is connected to the partial pattern 76D1. The partial pattern 7602 projects out in the +X direction. One end of the partial pattern 76D3 is connected to the partial pattern 76D2. A longitudinal direction of the partial pattern 76D3 is the Y direction. The partial pattern 76D3 projects out in the +Y direction. The partial pattern 76D3 projects out so as to follow along the longitudinal direction of the partial pattern 76A3. One end of the partial pattern 76D4 is connected to the partial pattern 76D1. A longitudinal direction of the partial pattern 76D4 is the Y direction. The partial pattern 76D4 projects out in the +Y direction. The partial pattern 76D4 projects out so as to follow along the longitudinal direction of the partial pattern 76A3. A longitudinal direction of the partial pattern 76D5 is the X direction. One end of the partial pattern 76D5 is connected to the partial pattern 76D1. The partial pattern 76D5 projects out in the −X direction. One end of the partial pattern 76D6 is connected to another end of the partial pattern 76D5. A longitudinal direction of the partial pattern 76D6 is the Y direction. The partial pattern 76D6 projects out in the −Y direction. Specifically, the partial pattern 76D6 projects out toward the side surface 14e.

The partial pattern 76A3 and the partial pattern 76D6 are adjacent to each other. Since the partial pattern 76A3 and the partial pattern 76D6 are adjacent to each other, the coupling capacitance electrode 76A and the coupling capacitance electrode 76D are capacitively coupled. A capacitive coupling structure 77A is constituted by the coupling capacitance electrode 76A and the coupling capacitance electrode 76D.

The position in the Y direction of the partial pattern 76A2 is equivalent to the position in the Y direction of the partial pattern 76D5. Both of the partial pattern 76A3 and the partial pattern 76D6 project out in the −Y direction. Specifically, the partial pattern 76A3 and the partial pattern 76D6 project out toward the side surface 14e. The positions in the Y direction of the partial patterns 76A3 and 76D6 are between the positions in the Y direction of the partial patterns 76A2 and 76D5 and the position in the Y direction of the shielding conductor 12Ca.

The reason why both of the partial pattern 76A3 and the partial pattern 76D6 are caused to project out toward the side surface 14e is as follows. Specifically, the reason why both of the partial pattern 76A3 and the partial pattern 76D6 are caused to project out in the −Y direction is as follows. In the case that the partial pattern 76A3 and the partial pattern 76D6 are both caused to project out in the +Y direction, the partial patterns 76A3 and 76D6 are in close proximity to the partial patterns 76C3 and 76C4 and the like. When the partial patterns 76A3, 76D6 and the partial patterns 76C3, 76C4 and the like, are in close proximity to each other, the partial patterns 76A3, 76D6 and the partial patterns 76C3, 76C4 and the like are capacitively coupled to each other. It is not preferable for the partial patterns 76A3, 76D6 and the partial patterns 76C3, 76C4 and the like to be capacitively coupled to each other. On the other hand, in the case that the partial pattern 76A3 and the partial pattern 76D6 are both caused to project out in the −Y direction, the partial patterns 76A3 and 76D6 are not in close proximity to the partial patterns 76C3 and 76C4 and the like. Since the partial patterns 76A3 and 76D6 and the partial patterns 76C3 and 76C4 and the like are not in close proximity to each other, the partial patterns 76A3 and 76D6 and the partial patterns 76C3 and 76C4 and the like are not capacitively coupled to each other. For this reason, according to the present embodiment, both of the partial pattern 76A3 and the partial pattern 76D6 are caused to project out toward the side surface 14e.

The partial pattern 76B3 and the partial pattern 76C6 are adjacent to each other. Since the partial pattern 76B3 and the partial pattern 76C6 are adjacent to each other, the coupling capacitance electrode 76B and the coupling capacitance electrode 76C are capacitively coupled. A capacitive coupling structure 77B is constituted by the coupling capacitance electrode 76B and the coupling capacitance electrode 76C.

The position in the Y direction of the partial pattern 76B2 is equivalent to the position in the Y direction of the partial pattern 76C5. Both of the partial pattern 76B3 and the partial pattern 76C6 project out in the +Y direction. Specifically, the partial pattern 76B3 and the partial pattern 76C6 project out toward the side surface 14f. The positions in the Y direction of the partial patterns 76B3 and 76C6 are between the positions in the Y direction of the partial patterns 76B2 and 76C5 and the position in the Y direction of the shielding conductor 12Cb.

The reason why both of the partial pattern 76B3 and the partial pattern 76C6 are caused to project out toward the side surface 14f is as follows. Specifically, the reason why both of the partial pattern 76B3 and the partial pattern 76C6 are caused to project out in the +Y direction is as follows. In the case that the partial pattern 76B3 and the partial pattern 76C6 are both caused to project out in the −Y direction, the partial patterns 76B3 and 76C6 are in close proximity to the partial patterns 76D3 and 76D4 and the like. When the partial patterns 76B3 and 76C6 and the partial patterns 76D3 and 76D4 and the like are in close proximity to each other, the partial patterns 76B3 and 76C6 and the partial patterns 76D3 and 76D4 and the like are capacitively coupled to each other. It is not preferable for the partial patterns 76B3, 76C6 and the partial patterns 76D3, 76D4 and the like to be capacitively coupled to each other. On the other hand, in the case that the partial pattern 76B3 and the partial pattern 76C6 are both caused to project out in the +Y direction, the partial patterns 76B3 and 76C6 are not in close proximity to the partial patterns 76D3 and 76D4 and the like. Since the partial patterns 76B3 and 76C6 and the partial patterns 76D3 and 76D4 and the like are not in close proximity to each other, the partial patterns 76B3 and 76C6 and the partial patterns 76D3 and 76D4 and the like are not capacitively coupled to each other. For this reason, according to the present embodiment, both of the partial pattern 76B3 and the partial pattern 76C6 are caused to project out toward the side surface 14f.

The partial pattern 76A4 and the partial pattern 76C3 are adjacent to each other. Since the partial pattern 76A4 and the partial pattern 76C3 are adjacent to each other, the coupling capacitance electrode 76A and the coupling capacitance electrode 76C are capacitively coupled. A capacitive coupling structure 77C is constituted by the coupling capacitance electrode 76A and the coupling capacitance electrode 76C.

The partial pattern 76B4 and the partial pattern 76D3 are adjacent to each other. Since the partial pattern 76B4 and the partial pattern 76D3 are adjacent to each other, the coupling capacitance electrode 76B and the coupling capacitance electrode 76D are capacitively coupled. A capacitive coupling structure 77D is constituted by the coupling capacitance electrode 76B and the coupling capacitance electrode 76D.

The partial pattern 76C4 and the partial pattern 76D4 are adjacent to each other. Since the partial pattern 76C4 and the partial pattern 76D4 are adjacent to each other, the coupling capacitance electrode 76C and the coupling capacitance electrode 76D are capacitively coupled. A capacitive coupling structure 77E is constituted by the coupling capacitance electrode 76C and the coupling capacitance electrode 76D.

As shown in FIG. 9, coupling capacitance electrodes (comb-tooth or interdigitated electrodes) 78A to 78C are formed within the dielectric substrate 14. The coupling capacitance electrodes 78A to 78C are formed in the same layer. Stated otherwise, the coupling capacitance electrodes 78A to 78C are formed on the same ceramic sheet (not shown). When the individual coupling capacitance electrodes are described without distinguishing therebetween, the reference numeral 78 will be used, and when the individual coupling capacitance electrodes are described while distinguishing therebetween, the reference numerals 78A to 78C will be used. One or more non-illustrated ceramic sheets exist between the coupling capacitance electrodes 76 and the coupling capacitance electrodes 78.

The coupling capacitance electrodes 78 are arranged at positions that are point symmetrical, with the center C of the dielectric substrate 14 (refer to FIG. 2) as viewed in plan serving as the center of symmetry. The coupling capacitance electrode 78A and the coupling capacitance electrode 78B are arranged at positions that are point symmetrical, with the center C of the dielectric substrate 14 as viewed in plan serving as the center of symmetry. Further, the coupling capacitance electrode 78C is also formed in point symmetry, with the center C of the dielectric substrate 14 as viewed in plan serving as the center of symmetry. In the present embodiment, the feature in which the coupling capacitance electrodes 78 are disposed in point symmetry is in order to obtain satisfactory frequency characteristics.

As shown in FIG. 10, the coupling capacitance electrode 78A includes partial patterns 78A1 and 78A2. The partial pattern 78A1 is connected to the via electrode portion 20A. A longitudinal direction of the partial pattern 78A2 is the Y direction.

The coupling capacitance electrode 78B includes partial patterns 78B1 and 78B2. The partial pattern 78B1 is connected to the via electrode portion 20D. A longitudinal direction of the partial pattern 78B2 is the Y direction.

The coupling capacitance electrode 78C includes partial patterns 78C1 to 78C3. A longitudinal direction of the partial pattern 78C1 is the Y direction. The partial pattern 78C1 is adjacent to the partial pattern 78A2. A longitudinal direction of the partial pattern 78C2 is the Y direction. The partial pattern 78C2 is adjacent to the partial pattern 78B2. One end of the partial pattern 78C3 (a relay pattern) is connected to the partial pattern 78C1. Another end of the partial pattern 78C3 is connected to the partial pattern 78C2. Since the partial pattern 78A2 and the partial pattern 78C1 are adjacent to each other, the coupling capacitance electrode 78A and the coupling capacitance electrode 78C are capacitively coupled. Since the partial pattern 78B2 and the partial pattern 78C2 are adjacent to each other, the coupling capacitance electrode 78B and the coupling capacitance electrode 78C are capacitively coupled.

As shown in FIG. 9, input/output patterns 80A and 80B are further formed within the dielectric substrate 14. The input/output patterns 80A and 80B are formed in the same layer. Stated otherwise, the input/output patterns 80A and 80B are formed on the same ceramic sheet (not shown). When the individual input/output patterns are described without distinguishing therebetween, the reference numeral 80 will be used, and when the individual input/output patterns are described while distinguishing therebetween, the reference numerals 80A and 80B will be used. One or more non-illustrated ceramic sheets exist between the coupling capacitance electrodes 78 and the input/output patterns 80.

As shown in FIG. 10, the input/output pattern 80A includes partial patterns 80A1 to 80A2. One end of the partial pattern 80A1 is connected to the input/output terminal 22A. Another end of the partial pattern 80A1 is connected to the partial pattern 80A2. The partial pattern 80A2 is connected to the via electrode portion 20A. In this manner, the input/output terminal 22A is connected to the via electrode portion 20A via the input/output pattern 80A.

The input/output pattern 80B includes partial patterns 80B1 and 80B2. One end of the partial pattern 80B1 is connected to the input/output terminal 22B. Another end of the partial pattern 80B1 is connected to the partial pattern 80B2. The partial pattern 80B2 is connected to the via electrode portion 20D. In this manner, the input/output terminal 22B is connected to the via electrode portion 20D via the input/output pattern 80B.

In this manner, the input/output terminal 22A is electrically connected to the via electrode portion 20A via the input/output pattern 80A, and the input/output terminal 22B is electrically connected to the via electrode portion 20D via the input/output pattern 80B. According to the present embodiment, an external Q can be adjusted appropriately by appropriately setting the positions in the Z direction of the input/output patterns 80A and 80B. Specifically, according to the present embodiment, the external Q can be appropriately adjusted by appropriately setting the positions of the input/output patterns 80A and 80B in the longitudinal direction of the via electrode portions 20A and 20D.

As shown in FIG. 9, shielding via electrode portions 81A to 81D are formed in the dielectric substrate 14. When the individual shielding via electrode portions are described without distinguishing therebetween, the reference numeral 81 will be used, and when the shielding via electrode portions are described while distinguishing therebetween, the reference numerals 81A to 81D will be used.

A shielding via electrode 82A and a shielding via electrode 82B are provided in the shielding via electrode portion 81A. A shielding via electrode 82C and a shielding via electrode 82D are provided in the shielding via electrode portion 81B. A shielding via electrode 82E and a shielding via electrode 82F are provided in the shielding via electrode portion 81C. A shielding via electrode 82G and a shielding via electrode 82H are provided in the shielding via electrode portion 81D. When the individual shielding via electrodes are described without distinguishing therebetween, the reference numeral 82 will be used, and when the individual shielding via electrodes are described while distinguishing therebetween, the reference numerals 82A to 82H will be used. In the example shown in FIG. 9, although one of the shielding via electrode portions 81 is provided with two of the shielding via electrodes 82, one of the shielding via electrode portions 81 may be constituted by one of the shielding via electrodes 82.

One end of each of the shielding via electrode portions 81 is connected to the shielding conductor 12A. Another end of each of the shielding via electrode portions 81 is connected to the shielding conductor 12B.

As shown in FIG. 11, the shielding via electrode portion 81A is connected to the shielding conductors 12A and 12B, within an extending region 84A in which the region in which the via electrode portion 20A is positioned is extended in the −Y direction. Specifically, the shielding via electrode portion 81A is connected to the shielding conductors 12A and 12B, within the extending region 84A in which the region in which the via electrode portion 20A is positioned is extended toward the shielding conductor 12Ca. In this manner, the shielding via electrode portion 81A is selectively formed within the extending region 84A. The shielding via electrode portion 81A is positioned in the vicinity of the shielding conductor 12Ca. Moreover, the region in which the via electrode portions 20 are positioned corresponds to the imaginary ring 26.

The shielding via electrode portion 81B is connected to the shielding conductors 12A and 12B, within an extending region 84D in which the region in which the via electrode portion 20D is positioned is extended in the +Y direction. Specifically, the shielding via electrode portion 81B is connected to the shielding conductors 12A and 12B, within the extending region 84D in which the region in which the via electrode portion 20D is positioned is extended toward the shielding conductor 12Cb. The shielding via electrode portion 81B is selectively formed within an extending region 84B. The shielding via electrode portion 81B is positioned in the vicinity of the shielding conductor 12Cb.

The shielding via electrode portion 81C is connected to the shielding conductors 12A and 12B, within the extending region 84B in which the region in which the via electrode portion 20B is positioned is extended in the +Y direction. Specifically, the shielding via electrode portion 81C is connected to the shielding conductors 12A and 12B, within the extending region 84B in which the region in which the via electrode portion 20B is positioned is extended toward the shielding conductor 12Ca. The shielding via electrode portion 81C is selectively formed within the extending region 84B. The shielding via electrode portion 81C is positioned in the vicinity of the shielding conductor 12Cb.

The shielding via electrode portion 81D is connected to the shielding conductors 12A and 12B, within an extending region 84C in which the region in which the via electrode portion 20C is positioned is extended in the −Y direction. Specifically, the shielding via electrode portion 81D is connected to the shielding conductors 12A and 12B, within the extending region 84C in which the region in which the via electrode portion 20C is positioned is extended toward the shielding conductor 12Cb. The shielding via electrode portion 81D is selectively formed within the extending region 84C. The shielding via electrode portion 81D is positioned in the vicinity of the shielding conductor 12Ca. When the individual extending regions are described without distinguishing therebetween, the reference numeral 84 will be used, and when the individual extending regions are described while distinguishing therebetween, the reference numerals 84A to 84D will be used.

In the present embodiment, the shielding via electrode portions 81 are formed for the following reason. Specifically, when a positional shifting occurs in the case that the dielectric substrate 14 is cut, the distances between the via electrode portions 20 and the side surfaces 14e and 14f vary. When the distances between the via electrode portions 20 and the side surfaces 14e and 14f vary, the distances between the via electrode portions 20 and the shielding conductors 12Ca and 12Cb also vary. The variation in the distances between the via electrode portions 20 and the shielding conductors 12Ca and 12Cb brings about the variation in the filter characteristics and the like. On the other hand, since the shielding via electrode portions 81 are not formed on the side surfaces 14e and 14f, they do not receive an influence of any positional shifting that occurs when the dielectric substrate 14 is cut. Specifically, even in the case that a positional shifting occurs when the dielectric substrate 14 is cut, the distances between the shielding via electrode portions 81 and the via electrode portions 20 do not change. Due to such a reason, according to the present embodiment, the shielding via electrode portions 81 are formed.

In the present embodiment, the shielding via electrode portions 81 are selectively formed within the extending regions 84 for the following reason. Specifically, the shielding via electrode portions 81 can be formed by forming the via holes by irradiating the dielectric substrate 14 with a laser beam, and then by filling the via holes with a conductor. In particular, a certain amount of man-hours is required in order to form the shielding via electrode portions 81. For this reason, when a large number of the shielding via electrode portions 81 are simply arranged along the side surfaces 14e and 14f, satisfactory productivity cannot be obtained. On the other hand, by simply arranging the shielding via electrode portions 81 only in the extending regions 84, it is possible to suppress the variation in the filter characteristics and the like caused by the occurrence of positional shifting when the dielectric substrate 14 is cut. Due to such a reason, according to the present embodiment, the shielding via electrode portions 81 are selectively formed within the extending regions 84.

In this manner, according to the present embodiment, the dimension L1 of the regions 73A2, 73A3, 73B2, 73B3, 73C2, 73C3, 73D2, and 73D3 in the widthwise direction of the coupling capacitance electrodes 72A and 72B is set to be comparatively large. Therefore, according to the present embodiment, even in the case that a positional shifting occurs at the time of manufacturing, the variation in the capacitance of the capacitive coupling structures 71A and 71B can be suppressed. For this reason, according to the present embodiment, it is possible to obtain the filter 10 that exhibits satisfactory characteristics.

### Modified Embodiments

The present invention is not necessarily limited to the above-described embodiment, and various configurations can be adopted therein without departing from the essence and gist of the present invention.

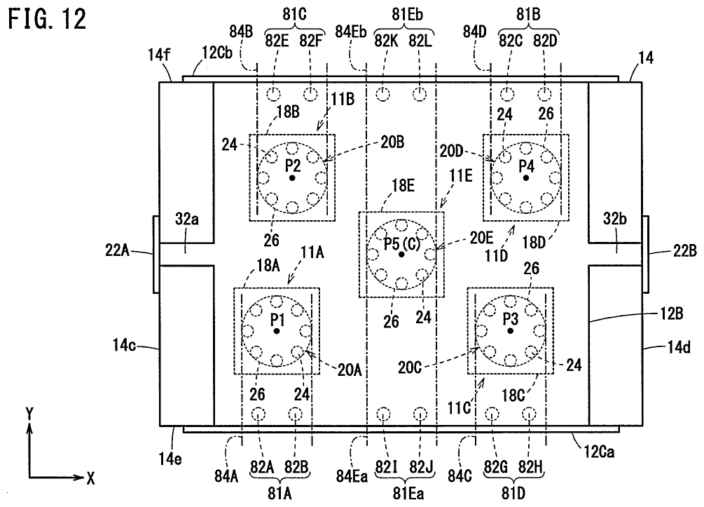

For example, in the above-described embodiment, a description has been given of a case in which the filter 10 is equipped with four of the resonators 11. However, the present invention is not necessarily limited to this feature. For example, the filter 10 may be equipped with five of the resonators 11. FIG. 12 is a plan view showing an example of the filter according to a modified embodiment. An example of a case in which five of the resonators 11 are provided in the filter 10 is shown in FIG. 12. As shown in FIG. 12, the filter 10 is equipped with five of resonators 11A to 11E. Specifically, the filter 10 is equipped with the resonator 11A, the resonator 11B, the resonator 11C, the resonator 11D, and the resonator 11E. Moreover, when the individual resonators are described without distinguishing therebetween, the reference numeral 11 will be used, and when the individual resonators are described while distinguishing therebetween, the reference numerals 11A to 11E will be used.

A capacitor electrode 18A and a via electrode portion 20A are provided in the resonator 11A. A capacitor electrode 18B and a via electrode portion 20B are provided in the resonator 11B. A capacitor electrode 18C and a via electrode portion 20C are provided in the resonator 11C. A capacitor electrode 18D and a via electrode portion 20D are provided in the resonator 11D. A capacitor electrode 18E and a via electrode portion 20E are provided in the resonator 11E.

The resonator 11A and the resonator 11B are arranged so as to be adjacent to each other. The resonator 11B and the resonator 11E are arranged so as to be adjacent to each other. The resonator 11E and the resonator 11C are arranged so as to be adjacent to each other. The resonator 11C and the resonator 11D are arranged so as to be adjacent to each other. An input/output terminal 22A is coupled to a shielding conductor 12B via an input/output pattern 32a. Further, an input/output terminal 22B is coupled to the shielding conductor 12B via an input/output pattern 32b.

The via electrode portion 20A, the via electrode portion 20B, the via electrode portion 20E, the via electrode portion 20C, and the via electrode portion 20D are shifted mutually from each other in the X direction. The position of a center P5 of the via electrode portion 20E is the same as the position of the center C of the dielectric substrate 14. The distance between the via electrode portion 20E and a shielding conductor 12Ca is equivalent to the distance between the via electrode portions 20E and a shielding conductor 12Cb.

The position in the X direction of the center P5 of the via electrode portion 20E is between the position in the X direction of a center P1 of the via electrode portion 20A, and the position in the X direction of a center P4 of the via electrode portion 20D. Preferably, the distance between the position in the X direction of the center P5 of the via electrode portion 20E and the position in the X direction of the center P1 of the via electrode portion 20A is equivalent to the distance between the position in the X direction of the center P5 of the via electrode portion 20E and the position in the X direction of the center P4 of the via electrode portion 20D.

The position in the Y direction of the center P5 of the via electrode portion 20E is between the position in the Y direction of the center P1 of the via electrode portion 20A, and the position in the Y direction of the center P4 of the via electrode portion 20D. Preferably, the distance between the position in the Y direction of the center P5 of the via electrode portion 20E and the position in the Y direction of the center P1 of the via electrode portion 20A is equivalent to the distance between the position in the Y direction of the center P5 of the via electrode portion 20E and the position in the Y direction of the center P4 of the via electrode portion 20D.

The position in the Y direction of the center P1 of the via electrode portion 20A is equivalent to the position in the Y direction of a center P3 of the via electrode portion 20C. Similarly, the position in the Y direction of a center P2 of the via electrode portion 20B is equivalent to the position in the Y direction of the center P4 of the via electrode portion 20D.

The position in the X direction of the center P2 of the via electrode portion 20B is between the position in the X direction of the center P1 of the via electrode portion 20A, and the position in the X direction of the center P5 of the via electrode portion 20E. The position in the X direction of the center P3 of the via electrode portion 20C is between the position in the X direction of the center P4 of the via electrode portion 20D, and the position in the X direction of the center P5 of the via electrode portion 20E.

Shielding via electrode portions 81A to 81D, 81Ea, and 81Eb are formed inside the dielectric substrate 14. The shielding via electrode portions 81A to 81D are similar to the aforementioned shielding via electrode portions 81A to 81D, and therefore, a description of this feature will be omitted. A shielding via electrode 82I and a shielding via electrode 82J are provided in the shielding via electrode portion 81Ea. A shielding via electrode 82K and a shielding via electrode 82L are provided in the shielding via electrode portion 81Eb. When the individual shielding via electrode portions are described without distinguishing therebetween, the reference numeral 81 will be used, and when the shielding via electrode portions are described while distinguishing therebetween, the reference numerals 81A to 81D, 81Ea, and 81Eb will be used. One end of each of the shielding via electrode portions 81 is connected to a shielding conductor 12A. Another end of each of the shielding via electrode portions 81 is connected to a shielding conductor 12B.

The shielding via electrode portion 81Ea is connected to the shielding conductors 12A and 12B, within an extending region 84Ea in which the region in which the via electrode portion 20E is positioned is extended in the −Y direction. Specifically, the shielding via electrode portion 81Ea is connected to the shielding conductors 12A and 12B, within the extending region 84Ea in which the region in which the via electrode portion 20E is positioned is extended toward the shielding conductor 12Ca. In this manner, the shielding via electrode portion 81Ea is selectively formed within the extending region 84Ea. The shielding via electrode portion 81Ea is positioned in the vicinity of the shielding conductor 12Ca.

The shielding via electrode portion 81Eb is connected to the shielding conductors 12A and 12B, within an extending region 84Eb in which the region in which the via electrode portion 20E is positioned is extended in the +Y direction. Specifically, the shielding via electrode portion 81Eb is connected to the shielding conductors 12A and 12B, within the extending region 84Eb in which the region in which the via electrode portion 20E is positioned is extended toward the shielding conductor 12Cb. In this manner, the shielding via electrode portion 81Eb is selectively formed within the extending region 84Eb. The shielding via electrode portion 81Eb is positioned in the vicinity of the shielding conductor 12Cb.

In this manner, the filter 10 may be equipped with five of the resonators 11.

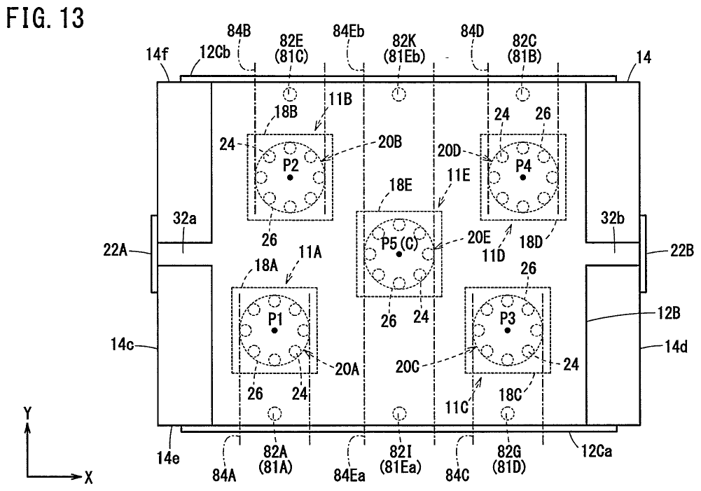

FIG. 13 is a plan view showing an example of the filter according to a modified embodiment. In the example shown in FIG. 13, one of shielding via electrode portions 81 is constituted by one of shielding via electrodes 82. A shielding via electrode portion 81A is constituted by a shielding via electrode 82A. A shielding via electrode portion 81B is constituted by a shielding via electrode 82C. A shielding via electrode portion 81C is constituted by a shielding via electrode 82E. A shielding via electrode portion 81D is constituted by a shielding via electrode 82G. A shielding via electrode portion 81Ea is constituted by a shielding via electrode 82I. A shielding via electrode portion 81Eb is constituted by a shielding via electrode 82K. In this manner, one of the shielding via electrode portions 81 may be constituted by one of the shielding via electrodes 82.

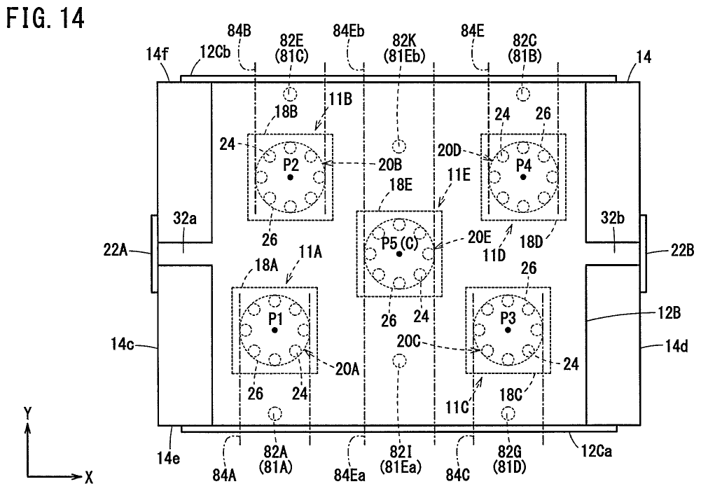

FIG. 14 is a plan view showing an example of the filter according to a modified embodiment. In the example shown in FIG. 14, a shielding via electrode portion 81Ea is positioned at a position in the middle between the via electrode portion 20E and the shielding conductor 12Ca. In the example shown in FIG. 14, the shielding via electrode portion 81Ea is not positioned in the vicinity of the shielding conductor 12Ca. The distance in the Y direction between the shielding via electrode portion 81Ea and the shielding conductor 12Ca is greater than the distance in the Y direction between the shielding via electrode portions 81A and 81D and the shielding conductor 12Ca. In the example shown in FIG. 14, a shielding via electrode portion 81Eb is positioned at a position in the middle between the via electrode portion 20E and the shielding conductor 12Cb. Specifically, in the example shown in FIG. 14, the shielding via electrode portion 81Eb is not positioned in the vicinity of the shielding conductor 12Cb. The distance in the Y direction between the shielding via electrode portion 81Eb and the shielding conductor 12Cb is greater than the distance in the Y direction between the shielding via electrode portions 81B and 81C and the shielding conductor 12Cb. In this manner, the shielding via electrode portion 81Ea may be positioned at a position in the middle between the via electrode portion 20E and the shielding conductor 12Ca. Further, the shielding via electrode portion 81Eb may be positioned at a position in the middle between the via electrode portion 20E and the shielding conductor 12Cb.

Further, the filter 10 may be equipped with six or more of the resonators 11.

In the above embodiment, although a description has been given in which the input/output terminals 22A and 22B are connected to the via electrode portions 20A and 20D via the input/output patterns 80A and 80B, the present invention is not necessarily limited to this feature. For example, the input/output terminals 22A and 22B may be connected to the shielding conductor 12B via the input/output patterns 32a and 32b (refer to FIG. 12).

Further, in the modified embodiments discussed above using FIG. 12 to FIG. 14, although an example was described in which the input/output terminals 22A and 22B are connected to the shielding conductor 12B via the input/output patterns 32a and 32b, the present invention is not necessarily limited to this feature. For example, the input/output terminals 22A and 22B may be connected to the via electrode portions 20A and 20D via the input/output patterns 80A and 80B (refer to FIG. 2).

A description will be given below concerning the inventions that are capable of being grasped from the above-described embodiment.

The filter (10) includes the plurality of resonators (11A to 11D) formed inside the dielectric substrate (14), and each of which is equipped with the via electrode portion (20A to 20D), and the first capacitive coupling structure (71A, 71E) including the first electrode pattern (70A3, 70E) connected to any one from among the plurality of via electrode portions, the second electrode pattern (70C2, 70F) connected to any one from among the plurality of via electrode portions, and the first coupling capacitance electrode (72A, 72E) one end of which overlaps the first electrode pattern as viewed in plan, and another end of which overlaps the second electrode pattern as viewed in plan, wherein the dimension (W12) of the first coupling capacitance electrode in the widthwise direction of the first coupling capacitance electrode is smaller than the dimension (W11) of the first electrode pattern in the widthwise direction of the first coupling capacitance electrode, on both sides of the first region (73A1) in which the first coupling capacitance electrode and the first electrode pattern overlap, there exist the second regions (73A2, 73A3) in which the first coupling capacitance electrode does not overlap with the first electrode pattern, and the first dimensional difference (W11-W12), which is a value obtained by subtracting the dimension of the first coupling capacitance electrode in the widthwise direction of the first coupling capacitance electrode from the dimension of the first electrode pattern in the widthwise direction of the first coupling capacitance electrode, is greater than or equal to 1.4 times the first inter-electrode distance (d1), which is the distance between the first coupling capacitance electrode and the first electrode pattern in the thickness direction of the first coupling capacitance electrode. In accordance with such a configuration, since the first dimensional difference is set to be comparatively large, even in the case that a positional shifting has occurred at the time of manufacturing, the variation in the capacitance of the first capacitive coupling structure can be favorably suppressed. Therefore, in accordance with such a configuration, the filter having satisfactory characteristics can be obtained.

In the above-described filter, the first dimensional difference may be greater than or equal to 2.6 times the first inter-electrode distance. In accordance with such a configuration, the variation in the capacitance of the first capacitive coupling structure can be more favorably suppressed. Therefore, in accordance with such a configuration, the filter having more satisfactory characteristics can be obtained.

In the above-described filter, there may further be provided the second capacitive coupling structure (71C) including the third electrode pattern (70A2) connected to the first via electrode portion (20A) from among the plurality of via electrode portions, the fourth electrode pattern (70D3) connected to the second via electrode portion (20C) from among the plurality of via electrode portions, and the second coupling capacitance electrode (72C) one end of which overlaps the third electrode pattern as viewed in plan, and the other end of which overlaps the fourth electrode pattern as viewed in plan, wherein the dimension of the second coupling capacitance electrode in the widthwise direction of the second coupling capacitance electrode may be smaller than the dimension of the third electrode pattern in the widthwise direction of the second coupling capacitance electrode, on both sides of the third region (73E1) in which the second coupling capacitance electrode and the third electrode pattern overlap, there exist the fourth regions (73E2, 73E3) in which the second coupling capacitance electrode does not overlap with the third electrode pattern, the first via electrode portion may be positioned on the extending region of the one end of the second coupling capacitance electrode, the second via electrode portion may be positioned on the extending region of the other end of the second coupling capacitance electrode, none from among the plurality of via electrode portions may be positioned on the extending region of at least one end of the first coupling capacitance electrode, and the second dimensional difference (W21-W22), which is a value obtained by subtracting the dimension (W22) of the second coupling capacitance electrode in the widthwise direction of the second coupling capacitance electrode from the dimension (W21) of the third electrode pattern in the widthwise direction of the second coupling capacitance electrode, may be greater than or equal to 1.4 times the second inter-electrode distance (d1), which is the distance between the second coupling capacitance electrode and the third electrode pattern in the thickness direction of the second coupling capacitance electrode, and the first dimensional difference may be greater than the second dimensional difference.

In the above-described filter, the first electrode pattern may be connected to the first via electrode portion, the second electrode pattern may be connected to the third via electrode portion (20B) from among the plurality of via electrode portions, the second via electrode portion may be shifted in the first direction (+X) with respect to the first via electrode portion, the third via electrode portion may be shifted in the first direction with respect to the first via electrode portion, and may be shifted in the second direction (+Y) that intersects the first direction with respect to the first via electrode portion, the longitudinal direction of the first coupling capacitance electrode may be the second direction, and the longitudinal direction of the second coupling capacitance electrode may be the first direction.

In the above-described filter, the dielectric substrate may be equipped with the two main surfaces (14a, 14b), and the four side surfaces (14c to 14f), the distance between the first side surface (14e) from among the four side surfaces and the first via electrode portion may be smaller than the distance between the first side surface and the third via electrode portion, and the filter may further include the third capacitive coupling structure (77A) including the fifth electrode pattern (76A3) connected to the first via electrode portion and projecting toward the first side surface, and the sixth electrode pattern (76D6) connected to the second via electrode portion and projecting toward the first side surface.

In the above-described filter, the first side surface may be the side surface along the longitudinal direction of the dielectric substrate.

In the above-described filter, the first capacitive coupling structure (71E) may further include the third electrode pattern (74A3) connected to the via electrode portion (20B) that is connected to the first electrode pattern (70E), and overlapping the first electrode pattern as viewed in plan, and the fourth electrode pattern (74B3) connected to the via electrode portion (20C) that is connected to the second electrode pattern (70F), and overlapping the second electrode pattern as viewed in plan, and wherein the one end of the first coupling capacitance electrode may be sandwiched between the first electrode pattern and the third electrode pattern, and the other end of the first coupling capacitance electrode may be sandwiched between the second electrode pattern and the fourth electrode pattern.

In the above-described filter, the via electrode portions may be constituted by the plurality of via electrodes (24).

In the above-described filter, each of the plurality of resonators may include one of the via electrode portions.

In the above-described filter, the resonators may be equipped with the capacitor electrodes (18A to 18D) configured to face toward the first shielding conductor (12A) from among the plurality of shielding conductors (12A, 12B, 12Ca, 12Cb) formed to surround the via electrode portions, and configured to be connected to the one end of each of the via electrode portions.

The invention claimed is:

1. A filter comprising:
a plurality of resonators formed inside a dielectric substrate, and each of which is equipped with a via electrode portion; and
a first capacitive coupling structure including a first electrode pattern connected to any one from among the plurality of via electrode portions, a second electrode pattern connected to any one from among the plurality of via electrode portions, and a first coupling capacitance electrode one end of which overlaps the first electrode pattern as viewed in plan, and another end of which overlaps the second electrode pattern as viewed in plan,
wherein a dimension of the first coupling capacitance electrode in a widthwise direction of the first coupling capacitance electrode is smaller than a dimension of the first electrode pattern in the widthwise direction of the first coupling capacitance electrode;
on both sides of a first region in which the first coupling capacitance electrode and the first electrode pattern overlap, there exist second regions in which the first coupling capacitance electrode does not overlap with the first electrode pattern; and
a first dimensional difference, which is a value obtained by subtracting the dimension of the first coupling capacitance electrode in the widthwise direction of the first coupling capacitance electrode from the dimension of the first electrode pattern in the widthwise direction of the first coupling capacitance electrode, is greater than or equal to 1.4 times a first inter-electrode distance, which is a distance between the first coupling capacitance electrode and the first electrode pattern in a thickness direction of the first coupling capacitance electrode.

2. The filter according to claim 1, wherein the first dimensional difference is greater than or equal to 2.6 times the first inter-electrode distance.

3. The filter according to claim 1, further comprising a second capacitive coupling structure including a third electrode pattern connected to a first via electrode portion from among the plurality of via electrode portions, a fourth electrode pattern connected to a second via electrode portion from among the plurality of via electrode portions, and a second coupling capacitance electrode one end of which overlaps the third electrode pattern as viewed in plan, and another end of which overlaps the fourth electrode pattern as viewed in plan,
wherein:
a dimension of the second coupling capacitance electrode in a widthwise direction of the second coupling capacitance electrode is smaller than a dimension of the third electrode pattern in the widthwise direction of the second coupling capacitance electrode;
on both sides of a third region in which the second coupling capacitance electrode and the third electrode pattern overlap, there exist fourth regions in which the second coupling capacitance electrode does not overlap with the third electrode pattern;
the first via electrode portion is positioned on an extending region of the one end of the second coupling capacitance electrode;
the second via electrode portion is positioned on an extending region of the other end of the second coupling capacitance electrode;
none from among the plurality of via electrode portions is positioned on an extending region of at least one end of the first coupling capacitance electrode;
a second dimensional difference, which is a value obtained by subtracting a dimension of the second coupling capacitance electrode in the widthwise direction of the second coupling capacitance electrode from a dimension of the third electrode pattern in the widthwise direction of the second coupling capacitance electrode, is greater than or equal to 1.4 times a second inter-electrode distance, which is a distance between the second coupling capacitance electrode and the third electrode pattern in a thickness direction of the second coupling capacitance electrode; and
the first dimensional difference is greater than the second dimensional difference.

4. The filter according to claim 3, wherein:
the first electrode pattern is connected to the first via electrode portion;
the second electrode pattern is connected to a third via electrode portion from among the plurality of via electrode portions;
the second via electrode portion is shifted in a first direction with respect to the first via electrode portion;
the third via electrode portion is shifted in the first direction with respect to the first via electrode portion, and is shifted in a second direction that intersects the first direction with respect to the first via electrode portion;
a longitudinal direction of the first coupling capacitance electrode is the second direction; and
a longitudinal direction of the second coupling capacitance electrode is the first direction.

5. The filter according to claim 4, wherein:
the dielectric substrate is equipped with two main surfaces, and four side surfaces;
a distance between a first side surface from among the four side surfaces and the first via electrode portion is smaller than a distance between the first side surface and the third via electrode portion; and
the filter further comprises a third capacitive coupling structure including a fifth electrode pattern connected to the first via electrode portion and projecting toward the first side surface, and a sixth electrode pattern connected to the second via electrode portion and projecting toward the first side surface.

6. The filter according to claim 5, wherein the first side surface is a side surface along a longitudinal direction of the dielectric substrate.

7. The filter according to claim 1, wherein the first capacitive coupling structure further comprises a third electrode pattern connected to the via electrode portion that is connected to the first electrode pattern, and overlapping the first electrode pattern as viewed in plan, and a fourth electrode pattern connected to the via electrode portion that is connected to the second electrode pattern, and overlapping the second electrode pattern as viewed in plan, and wherein one end of the first coupling capacitance electrode is sandwiched between the first electrode pattern and the third electrode pattern, and another end of the first coupling capacitance electrode is sandwiched between the second electrode pattern and the fourth electrode pattern.

8. The filter according to claim 1, wherein the via electrode portions are constituted by a plurality of via electrodes.

9. The filter according to claim 1, wherein each of the plurality of resonators include one of the via electrode portions.

10. The filter according to claim 1, wherein the resonators are equipped with capacitor electrodes configured to face toward a first shielding conductor from among a plurality of shielding conductors formed to surround the via electrode portions, and configured to be connected to one end of each of the via electrode portions.
